(19) United States
(12) Patent Application Publication
(10) Pub. No.: US 2016/0284966 A1
(43) Pub. Date: Sep. 29, 2016

(54) LAYERED PRODUCT FOR MAGNETIC ELEMENT, THERMOELECTRIC CONVERSION ELEMENT HAVING LAYERED PRODUCT, AND METHOD OF MANUFACTURING THE SAME

(71) Applicants: NEC Corporation, Tokyo (JP); Tohoku University, Sendai (JP)

(72) Inventors: Akihiro KIRIHARA, Tokyo (JP); Masahiko ISHIDA, Tokyo (JP); Takashi MANAKO, Tokyo (JP); Kenichi UCHIDA, Sendai (JP); Eiji SAITOH, Miyagi (JP)

(73) Assignees: NEC Corporation, Tokyo (JP); Tohoku University, Sendai (JP)

(21) Appl. No.: 15/180,738

(22) Filed: Jun. 13, 2016

Related U.S. Application Data
(62) Division of application No. 14/232,750, filed on Apr. 24, 2014.

(30) Foreign Application Priority Data
Jul. 15, 2011 (JP) 2011-156618

(51) Int. Cl. H01L 37/04

(52) U.S. Cl. CPC H01L 37/04

(57) ABSTRACT

A magnetic element according to the present invention is formed of a layered product having a magnetic insulator film formed on a substrate including a material having no crystal structure. The magnetic insulator film has a columnar crystal structure.

### TECHNICAL FIELD

The present invention relates to a layered product for a magnetic element, a thermoelectric conversion element having such a layered product, and a method of manufacturing a layered product.

### BACKGROUND ART

The technology for depositing a high-quality magnetic crystalline film on a substrate has an important role in various applications such as information processing devices, information recording media, and energy conversion elements. Particularly, a “magnetic insulator,” which has magnetization due to spin polarization, such as a ferromagnetic material or a ferrimagnetic material, and is an electrically insulating material (a material having a low electric conductivity due to movement of free electrons), has been expected as a material that implements a spin device having a high energy efficiency and a low loss because it has less energy loss factors including spin scattering due to free electrons, eddy current, and the like.

In order to produce such a high-quality crystalline insulating film structure, monocrystalline substrates having close lattice constants have been used as templates. An epitaxial growth method of growing a crystalline film on a monocrystalline substrate so as to achieve lattice matching has primarily been used. A chemical vapor deposition (CVD) method using a gaseous material, a liquid-phase epitaxy (LPE) method using a liquid material, and a molecular beam epitaxy (MBE) method using a molecular beam material have been known as such epitaxial growth methods.

With such a growth method, crystal grows with a template of a crystalline structure of an underlying substrate. A crystalline array structure is uniquely defined upon the initial growth. As a result, generation of grain boundaries or crystal defects is suppressed. Therefore, it is possible to produce a thin film structure of a monocrystalline film and a monocrystalline substrate.

Furthermore, apart from the aforementioned epitaxial growth methods, there have also been reported wet type deposition methods using a solution type material, such as a sol-gel method or a metal organic decomposition (MOD) method. With those methods, a material solution is applied onto a substrate and then heated and annealed for solidification. Thus, a thin film is formed. Different material solutions are used depending upon production methods or target materials. Generally, metal alkoxide or the like is used in a sol-gel method. Furthermore, an organic compound of a metal is dissolved in an organic solvent and used as a material solution in an MOD method. There has also been reported a method of producing a magnetic film using such a material solution (Patent Literature 1 and Non-Patent Literature 1). With those methods, deposition is often performed in the air or in an atmosphere of a specific gas. Particularly, those methods differ from other deposition methods in that crystallization progresses by taking in oxygen atoms or the like from an ambient gas upon annealing after application of the material.

Magnetic crystal film structures produced by those methods have been applied to various elements.

For example, according to Patent Literature 2, a magnetic insulator crystalline film of iron garnet is formed on a gadolinium gallium garnet (GGG) monocrystalline substrate through epitaxial growth by an LPE method. Thus, there has been developed a magnetic bubble memory that uses, as storage bits, circular magnetic domains in the magnetic crystalline film. In this case, the crystal lattice of the GGG substrate serves as seeds, and crystal growth of the magnetic crystalline film of iron garnet is performed so as to achieve lattice matching with such seeds.

Furthermore, in Patent Literature 3, a similar iron garnet magnetic insulator crystalline film structure formed by a vapor-phase epitaxy method is grown on a monocrystalline substrate by a CVD method.

Moreover, in recent years, there has been reported development of technology of information processing and thermoelectric conversion using a new degree of freedom, “spin currents,” which are currents of spin angular momentum. In such technology, there has been demanded a spin current transmission film that can suppress scattering of spin currents and has high crystal quality to transmit information or energy with high efficiency.

Non-Patent Literature 2 has reported a thermoelectric conversion element that applies a temperature gradient to a magnetic layer so as to generate currents of spin angular momentum (spin currents) and derives this energy as an electromotive force from a nearby metal film. In this element, the magnetic layer should preferably have a high-quality crystal structure in order to take thermally induced energy out. In a specific element structure of this example, an yttrium iron garnet (YIG) crystalline film, which is a magnetic material, is formed on a monocrystalline substrate of gadolinium gallium garnet (GGG) by an LPE method. Furthermore, a Pt metal film for deriving electric power is deposited on the YIG crystalline film by a sputtering method.

In a thermoelectric conversion element using this effect, an insulator having a low thermal conductivity can be used as a thermoelectric material. Therefore, it is possible to design a high-efficiency thermoelectric device having a high thermal insulation property. Furthermore, a thermoelectric module configured with a new degree of freedom, or spin currents, is remarkably simplified in structure as compared to a conventional thermoelectric module having a plurality of thermocouples being connected.

Furthermore, in Non-Patent Literature 3, there has been reported a logical operation element using the interference effect of a plurality of spin currents flowing through a magnetic film. Similarly, a YIG magnetic crystalline film is deposited on a GGG monocrystalline substrate. The YIG magnetic crystalline film serves as a spin current propagator. In this technology, the magnetic film should preferably have a high-quality crystal structure in order to suppress scattering of spin currents and to implement a highly reliable logical operation.

In this manner, expectations to a high-quality magnetic crystalline film have been raised in information processing, information recording, thermoelectric conversion, and the like. In those applications, it is best for the magnetic film to have perfect monocrystal. If a grain boundary surface (boundary between crystal grains having different crystal orientations) is perpendicular to the film surface, equivalent performance is demonstrated in many cases.

For example, in a thermoelectric conversion device that applies a temperature gradient in a direction perpendicular to a metal film/a magnetic film so as to generate electric power, spin currents are induced along this direction (perpendicular-plane direction: a direction perpendicular to the plane) in the magnetic film. In this case, if a grain boundary surface is present in parallel to the film surface in the magnetic film spin currents driven in the perpendicular-plane direction are scattered by disturbance of the crystal structure at the grain boundary surface. Accordingly, the thermoelectric conversion performance is degraded. In contrast, a grain boundary surface perpendicular to the film surface is less likely to scatter the perpendicular-plane spin currents and exert less influence on the performance.

For the foregoing reasons, a magnetic device as described above should preferably have a monoctystalline film structure having no grain boundary or a film structure having a plurality of areas where no grain boundary is present from a rear face to a front face of a magnetic film. In the latter case, specifically, a magnetic device is required to have a columnar crystal structure where crystal grains are sufficiently small with respect to the film thickness or where grain boundaries are produced only in a lateral direction.

### PRIOR ART LITERATURE

Patent Literature 1: JP-B 3743440

Patent Literature 2: JP-B 62-60756

Patent Literature 3: JP-A 60-10611

Non-Patent Literature 1: Journal of Crystal Growth 275, (2005) e2427-e2431

Non-Patent Literature 2: Nature Materials, Sep. 26, 2010, 894-897

Non-Patent Literature 3: Appl. Phys. Lett. 92, 022505 (2008)

Non-Patent Literature 4: Appl. Phys. Lett. 97, 252506

### SUMMARY OF INVENTION

### Problem(s) to be Solved by Invention

However, a conventional magnetic crystalline thin-film device as illustrated in Patent Literature 2 or 3 uses a monocrystalline substrate and adopts a structure of “magnetic monocrystalline film and a monocrystalline substrate” as a template for epitaxial crystal growth. Therefore, there have been the following four problems.

(1) A monocrystalline substrate itself is expensive, which prevents applications to inexpensive, general devices. Crystalline film growth has been impossible on an inexpensive, general amorphous substrate.

(2) There are limited combinations of a crystalline film and a monocrystalline substrate that can allow epitaxial growth. Specifically, a crystalline film and a monocrystalline substrate should share similar crystal structures having lattice constants matched within several percent. Accordingly, when a specific crystalline film is to be produced, choices of a substrate and a carrier that can be used for the specific crystalline film are considerably limited. Additionally, epitaxial growth of a homogeneous film requires an atomic level of flatness of a surface of the substrate. Thus, implementation of a device has been impossible on a surface having roughness or a curved surface.

(3) Even if a combination of a crystalline film and a substrate that have close lattice constants, perfect lattice matching is difficult. In most cases, strain resulting from a difference of the lattice constant accumulates during the growth of a film, or rearrangement occurs. Such strain or rearrangement induces loss or malfunction such as scattering of spin currents, thereby causing the device performance to be degraded.

(4) In most of epitaxial growth methods, a dedicated deposition apparatus that needs a high degree of control is required to obtain a high degree of vacuum or adjust an atmosphere. It has been difficult to achieve homogeneous large-area deposition and to produce highly productive devices.

The above problem (4) can be solved by using the aforementioned wet deposition process. However, it is difficult to grow a high-quality crystalline thin film on a non-crystalline substrate even by a sol-gel method or an MOD method. Therefore, the problems (1) to (3) cannot be solved.

In fact, Non-Patent Literature 1 suggests epitaxial production of a high-quality magnetic garnet crystalline film on a GGG monocrystalline substrate by an MOD method. However, there has been seen lowered crystal quality of a magnetic thin film deposited on a substrate of glass or silicon that does not function as a template for a crystalline film. The results of the film quality evaluation with an X-ray suggest that the magnetic thin film is polycrystalline with many boundaries.

Such a structure of “a magnetic polycrystalline film and an amorphous substrate” allows highly productive device implementation based upon an inexpensive substrate. On the other hand, such a structure of “a magnetic polycrystalline film and an amorphous substrate” cannot avoid degradation of the device performance such as increase of scattering of the spin freedom.

Particularly, unlike a “magnetic metal” material, which has a relatively simple crystal structure and is likely to provide stabilization of the crystal structure by movement of electrons, it has been difficult to form a stable crystal structure in a magnetic insulator material, which has less movement of electrons and is hard. It has been considered that a high-quality crystalline film cannot be produced on an amorphous substrate having no seeds for crystal growth even by using heating means such as excitation with plasma or high-temperature annealing.

As described above, conventional magnetic insulator crystalline film structures fall within either a high-quality and expensive structure of “a magnetic monocrystalline film and a monocrystalline substrate” with epitaxial growth or the like, or a low-quality and inexpensive structure of “a magnetic polycrystalline film and an amorphous substrate” with a wet process. There has not been known high-quality and inexpensive structures such as “a magnetic monocrystalline film and an amorphous substrate” or “a magnetic columnar crystalline film and an amorphous substrate,” which are desirable in applications.

For the sake of convenience, in the following description, crystal structures are distinguished as follows: A crystal structure having grain boundary surfaces with various orientations is referred to as “polycrystal,” and a crystal structure having only grain boundary surface substantially perpendicular to the film is referred to as “columnar crystal.”

An object of the present invention is to provide a layered product for a magnetic element that has a magnetic insulator crystalline film with high quality and inexpensiveness.

Furthermore, another object of the present invention is to provide a thermoelectric conversion element using the magnetic element of the layered product and a method of manufacturing a layered product.

### Means for Solving the Problems(s)

According to a first aspect of the present invention, there is provided a layered product for a magnetic element. In this layered product, a magnetic insulator crystalline film is formed on a substrate including a material having no crystal structure on its surface. No grain boundaries of crystal grains are present in the thickness direction within the magnetic insulator crystalline film. Particularly, it is preferable to use a combination of oxide materials for the magnetic insulator crystalline film and the substrate. The substrate may have an uneven structure on its surface.

Such a magnetic insulator crystalline film can be formed, for example, by applying an organic solution containing a metal material onto a substrate with a spin-coating method and annealing the substrate under proper conditions. If a crystalline oxide film is formed on an oxide substrate as an example of a combination of oxide materials, then the surface of the substrate serves as an adsorption film for oxygen. As a result, orientation of a crystal structure is likely to be directed to a specific direction. Therefore, a film close to monocrystal can also be obtained.

Furthermore, a thermoelectric conversion element according to a second aspect of the present invention is characterized in that a metal film (conductive film) that exhibits a spin-orbit interaction is formed above the magnetic insulator crystalline film of the layered product. The thermoelectric conversion element is configured to receive a temperature difference between a bottom surface and an upper surface of the thermoelectric conversion element. Therefore, an electromotive force is generated in the in-plane direction of the metal film.

Moreover, according to a third aspect of the present invention, a method of manufacturing a layered product for a magnetic element includes preparing a substrate including a material having no crystal structure on its surface and forming a magnetic insulator film on the substrate by a wet process. The forming of the magnetic insulator film includes applying a solution containing a magnetic insulator material onto the substrate, and then annealing the substrate under an atmosphere such that the surface of the substrate serves as an adsorption film for oxygen. Thus, the magnetic insulator film has a crystal structure, and no grain boundaries of crystal grains are present in the thickness direction within the magnetic insulator film.

According to a fourth aspect of the present invention, a method of manufacturing thermoelectric conversion element is characterized by including forming a conductive film that exhibits a spin-orbit interaction on the magnetic insulator film of the layered product for a magnetic element that has been manufactured by the aforementioned manufacturing method.

Furthermore, according to the present invention, there is provided a thermoelectric conversion method including using, as a high-temperature side, one surface of the aforementioned thermoelectric conversion element and using, as a low-temperature side, another surface of the thermoelectric conversion element to apply a temperature difference. The thermoelectric conversion method is characterized by using a surface near the magnetic insulator film as the low-temperature side. With this method, environmental heat can efficiently be utilized to obtain a high thermoelectric conversion output.

### Advantageous Effects of Invention

According to the present invention, there can be provided a layered product for a magnetic element that has a magnetic insulator crystalline film with high quality and inexpensiveness.

### BRIEF DESCRIPTION OF DRAWINGS

FIG. 1A is a diagram explanatory of a magnetic element according to a first embodiment of the present invention.

FIG. 1B is a diagram explanatory of desirable columnar crystal conditions of the magnetic element according to the first embodiment of the present invention.

FIG. 2 is a diagram showing Example 1 of a magnetic element as a specific example of the first embodiment of the present invention.

FIG. 3 is a diagram modeling a cross-sectional TEM photograph showing a film structure of Example 1 as a specific example of the first embodiment of the present invention (left side) and a diagram explanatory of a corresponding crystal structure (right side).

FIG. 4 is a diagram explanatory of a magnetic element according to a second embodiment of the present invention.

FIG. 5 is a diagram showing Example 2 of a magnetic element as a specific example of the second embodiment of the present invention.

FIG. 6 is a perspective view of a multilayered magnetic element according to a third embodiment of the present invention.

FIG. 7 is a diagram showing Example 3 of a multilayered magnetic element as a specific example of the third embodiment of the present invention.

FIG. 8A is a diagram explanatory of a thermoelectric conversion element according to a fourth embodiment of the present invention.

FIG. 8B is a diagram explanatory of desirable columnar crystal conditions of a magnetic film in the thermoelectric conversion element according to the fourth embodiment of the present invention.

FIG. 9 is a diagram explanatory of scaling law of the thermoelectric conversion element according to the fourth embodiment of the present invention.

FIG. 10 is a diagram explanatory of Example 4 of a thermoelectric conversion element as a specific example of the fourth embodiment of the present invention, including a figure modeling a microphotograph.

FIG. 11 is a diagram explanatory of a phonon drag effect in the thermoelectric conversion element in the fourth embodiment of the present invention.

FIG. 12 is a diagram for comparing (b) a crystal growth process of a structure of “a columnar crystalline film and an amorphous substrate” according to the present invention with (a) that of a conventionally known structure of “a polycrystalline film and an amorphous substrate.”

FIG. 13 is a diagram explanatory of experiment results for thermoelectromotive force performance of elements having the same structure as shown in FIG. 10 including (a) an element produced with a shortened primary annealing time and (b) an element produced with a sufficient primary annealing time.

FIG. 14 is a diagram for comparing (a) the quality of a magnetic insulator film produced by slowly increasing the temperature to a temporary annealing temperature in 8 minutes with (b) the quality of a magnetic insulator film produced by rapidly increasing the temperature to a temporary annealing temperature within 30 seconds, including figures modeling microphotographs.

FIG. 15 is a diagram explanatory of a thermoelectric conversion element according to a fifth embodiment of the present invention.

FIG. 16 is a diagram explanatory of Example 5 of a thermoelectric conversion element as a specific example of the fifth embodiment of the present invention.

FIG. 17 is a diagram showing a different example of a thermoelectric conversion element than Example 5 as a specific example of the fifth embodiment of the present invention.

FIG. 18 is a perspective view of a multilayered thermoelectric conversion element according to a sixth embodiment of the present invention.

FIG. 19 is a diagram showing Example 6 of a multilayered thermoelectric conversion element as a specific example of the sixth embodiment of the present invention.

FIG. 20 is a diagram explanatory of (b) an implementation example of a thermoelectric conversion function according to a seventh embodiment of the present invention as compared to (a) the prior art.

FIG. 21 is a diagram explanatory of a thermoelectric conversion function according to the seventh embodiment of the present invention.

FIG. 22 is a diagram explanatory of the phonon drag effect in the thermoelectric conversion function according to the seventh embodiment of the present invention.

FIG. 23 is a diagram explanatory of a magnetic element formed on an uneven surface according to an eighth embodiment of the present invention.

FIG. 24 is a diagram showing some examples of an uneven structure used in the eighth embodiment of the present invention.

FIG. 25 is a diagram showing Example 8 of a magnetic element formed on an uneven surface as a specific example of the eighth embodiment of the present invention, including a figure modeling a microphotograph.

FIG. 26 is a diagram explanatory of a thermoelectric conversion element according to a ninth embodiment of the present invention.

FIG. 27 is a diagram showing Example 9 of a thermoelectric conversion element as a specific example of the ninth embodiment of the present invention, including figures modeling microphotographs.

FIG. 28 is a diagram explanatory of a thermoelectric conversion function according to a tenth embodiment of the present invention.

FIG. 29 is a diagram explanatory of a method of implementing a thermoelectric conversion function according to the tenth embodiment of the present invention.

### MODE(S) FOR CARRYING OUT THE INVENTION

### First Embodiment

### A Magnetic Element of a Layered Product Including an Amorphous Substrate and a Magnetic Insulator Film

A first embodiment of the present invention will be described in detail with reference to the drawings.

### (Structure)

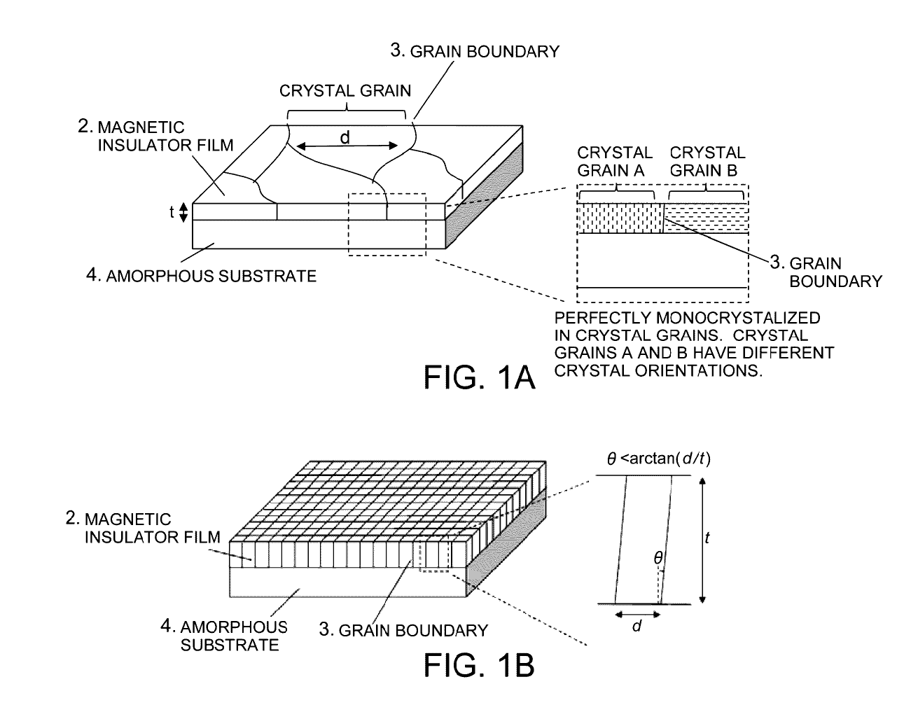

FIG. 1A shows a perspective view of a magnetic element according to a first embodiment of the present invention. The magnetic element of the first embodiment has a layered product of a magnetic insulator film (magnetic insulator crystalline film) 2 and an amorphous substrate 4 supporting the magnetic insulator film 2.

Here, a magnetic insulator refers to a material that is magnetic (a substance having magnetization due to spin polarization, such as a ferromagnetic material or a ferrimagnetic material) and is electrically insulated (a material having a low electric conductivity due to movement of free electrons).

The magnetic insulator film 2 of the first embodiment is a crystalline film formed of a magnetic insulator material having uniform chemical composition and has an atomic array structure that is single-grained in a direction perpendicular to a film surface of the element (perpendicular-plane direction). Specifically, as shown in FIG. 1A, a plurality of crystal grains having different crystal orientations may be present in the in-plane direction within the magnetic insulator film 2 while those crystal grains interpose grain boundaries 3 therebetween. Every surface of those grain boundaries extends substantially perpendicular to a surface of the magnetic insulator film 2 (so as to divide grains within the surface of the magnetic insulator film 2). In other words, no grain boundaries of crystal grains exist within the magnetic insulator film 2 in the thickness direction of the magnetic insulator film 2.

As a result, the magnetic insulator film 2 can be regarded as having perfect crystal orientation from a front face to a rear face of the film when the film surface is locally observed within a range of a single-grain length scale.

When applications to thermoelectric conversion elements or recording media are taken into consideration, the film thickness t of the magnetic insulator film 2 should preferably be at least 50 nm, and more preferably at least 300 nm in order to demonstrate high device performance. Similarly, in order to obtain high device performance, the average of the grain size d within the plane should preferably be at least the film thickness t of the magnetic insulator film 2 (d>t). More preferably, d>5t in order to ensure the favorable performance. Furthermore, it is preferable to have a plurality of grains having a grain size d of at least 1 μm irrespective of the film thickness t.

In a thermoelectric conversion element using a columnar crystal magnetic material according to the present invention described later or the like, spin currents thermally driven in the perpendicular-plane direction may reach the metal film 5 without being scattered in the thermoelectric conversion element. Therefore, as shown in FIG. 1B, a satisfactory device can be produced with a columnar crystal grain structure having a high aspect ratio under the conditions that surfaces of grain boundaries are substantially perpendicular to the film surface.

Under more preferable conditions for a columnar crystal structure, an inclination angle θ with respect to the perpendicular-plane direction of the grain boundary surface should preferably be set such that θ<arctan(d/t) from the viewpoint of minimizing the grain boundary scattering of the perpendicular-plane spin currents. For example, in a case of a columnar crystal grain structure where the grain size d=200 nm and the film thickness t=1 μm, the angle θ of the grain boundary surface is preferably set such that θ<arctan(0.2)=11.3°.

For example, magnetic oxide materials such as garnet ferrite or spinel ferrite may be applied to specific materials for the magnetic insulator film 2. Such a magnetic insulator crystalline film structure can be produced on various substrates by a wet process such as a metal organic decomposition method (MOD method) or a sol-gel method.

For example, a glass substrate made of silica glass or no-alkali glass may be used as the amorphous substrate 4. Other substrates made of a metal oxide may be used instead.

As specifically described in the following examples, when an oxide thin film grows on a surface (upper surface) of an oxide substrate, the crystal orientation at the time of the initial growth is defined by attachment of oxygen onto the surface of the substrate. As a result, the structure having a crystal orientation film that is close to monocrystal is likely to be produced. Therefore, in order to direct the crystal structure of the magnetic insulator film 2 to a specific direction, it is particularly preferable to use a combination of an amorphous oxide material for the amorphous substrate 4 and an oxide magnetic material for the magnetic insulator film 2.

### Advantageous Effects

Use of the aforementioned magnetic insulator crystalline film structure, performance degradation due to grain boundary scattering of spin currents can be avoided in a magnetic device that drives spin currents in a perpendicular-plane direction of a film, such as a magnetic recording medium or a thermoelectric conversion element.

### Example 1

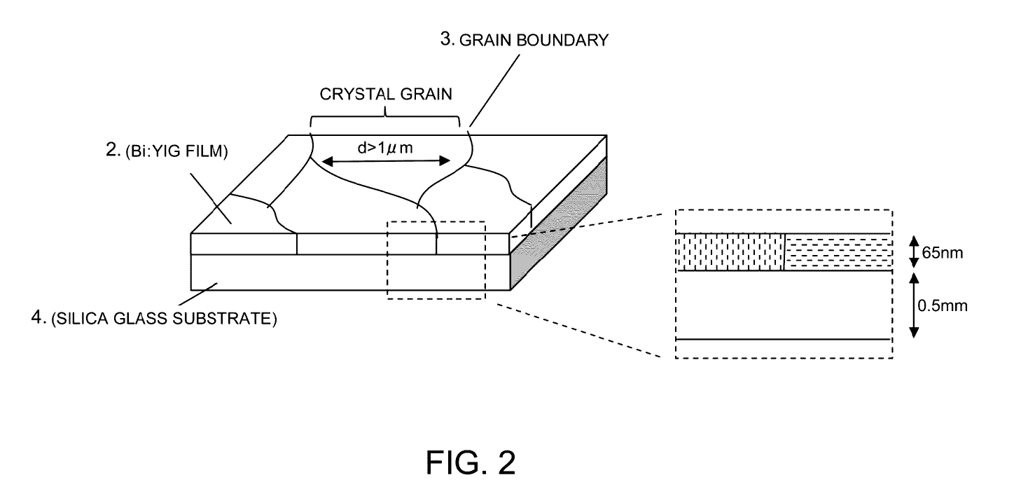

FIG. 2 shows Example 1 of the present invention. In this example, a silica glass substrate having a thickness of 0.5 mm is used as the amorphous substrate 4. Bismuth substitution yttrium iron garnet (Bi:YIG with a composition of BiY₂FesO₁₂) is used as the magnetic insulator film 2.

A Bi:YIG film is deposited by a metal organic decomposition method (MOD method). For example, a MOD solution manufactured by Kojundo Chemical Lab. Co., Ltd. is used for the Bi:YIG solution. Within this solution, a metal material with a proper mole fraction (Bi:Y:Fe=1:2:5) is calboxylated and dissolved in acetic ester at a concentration of 3%. This solution is applied onto the silica glass substrate 4 by a spin-coating method (with a rotation speed of 1.000 rpm and 30-second rotation). The silica glass substrate 4 is dried with a hot plate of 150° C. for 5 minutes. Then the silica glass substrate 4 is temporarily annealed at 550° C. for 5 minutes. Finally, the silica glass substrate 4 is primarily annealed at a high temperature of 720° C. in an electric furnace for 14 hours. Thus, the Bi:YIG film 2 having a film thickness of about 65 nm is formed on the silica glass substrate.

In order to obtain a thicker Bi:YIG film, the concentration or viscosity of the solution may be increased, or the aforementioned spin-coating deposition and heating process may be repeated a plurality of times. Thus, a thick film of 300 nm or more can be obtained.

Oxygen, which is one of primary elements of the Bi:YIG crystal structure, is taken from the air upon the last primary annealing. Thus, one of significant features of oxide crystal growth by a wet process is that crystal growth is dynamically performed by oxygen taken in from the outside.

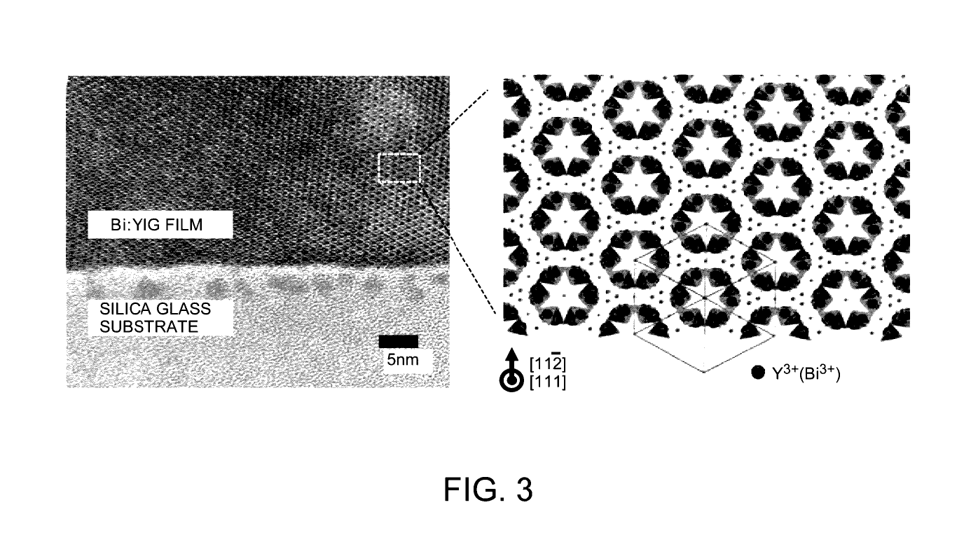

FIG. 3 is a photograph (left side) showing a cross-section of the produced Bi:YIG film observed with a transmission electron microscope. The photograph shows a Bi:YIG film that was close to monocrystal was formed on a silica glass substrate having no crystal structure. The grain size was far greater than the crystal film thickness. The inventors have confirmed that crystal orientation was aligned (monocrystalized) in an area having a size of at least 1 μm.

As explained in an eighth embodiment described later, generation of grain boundaries in a Bi:YIG film formed by a manufacturing method of Example 1 mostly results from an uneven structure of a substrate. It has been suggested that, when a substrate having high flatness is used, a crystal structure that is extremely close to monocrystal can be obtained.

As a result of the crystal structure analysis, the [111] crystal orientation of Bi:YIG is directed in parallel to the interface (the direction perpendicular to the paper in FIG. 3). The (11-2) surface contacts the interface with the silica glass substrate. One of significant features of this garnet (11-2) surface is that oxygen atoms are aligned with a high density on a two-dimensional plane. Oxygen has a property that it is likely to be attached to a surface of a silicon oxide such as glass. Upon annealing during the MOD deposition, oxygen in the air is attached to the surface (upper surface) of the silicon oxide. Thus, it is suggested that crystal orientation upon the initial growth is defined so that satisfactory crystal can grow in a state in which crystal orientation is aligned from a lower part of the Bi:YIG film to an upper part of the Bi:YIG film.

Specifically, although an amorphous material is used for a substrate, the aforementioned oxygen adsorption surface functions as an effective growth core, so that favorable crystal growth of Bi:YIG proceeds through the dynamic oxygen taking process.

When such a growth mechanism is taken into consideration, use of a combination of an amorphous oxide material for the amorphous substrate 4 and a magnetic oxide material for the magnetic insulator film 2 is particularly preferable in view of obtaining a favorable crystalline film structure, as with Example 1.

### Second Embodiment

### A Magnetic Element Including a Layered Product of an Amorphous Buffer Layer and a Magnetic Insulator Film

### (Structure)

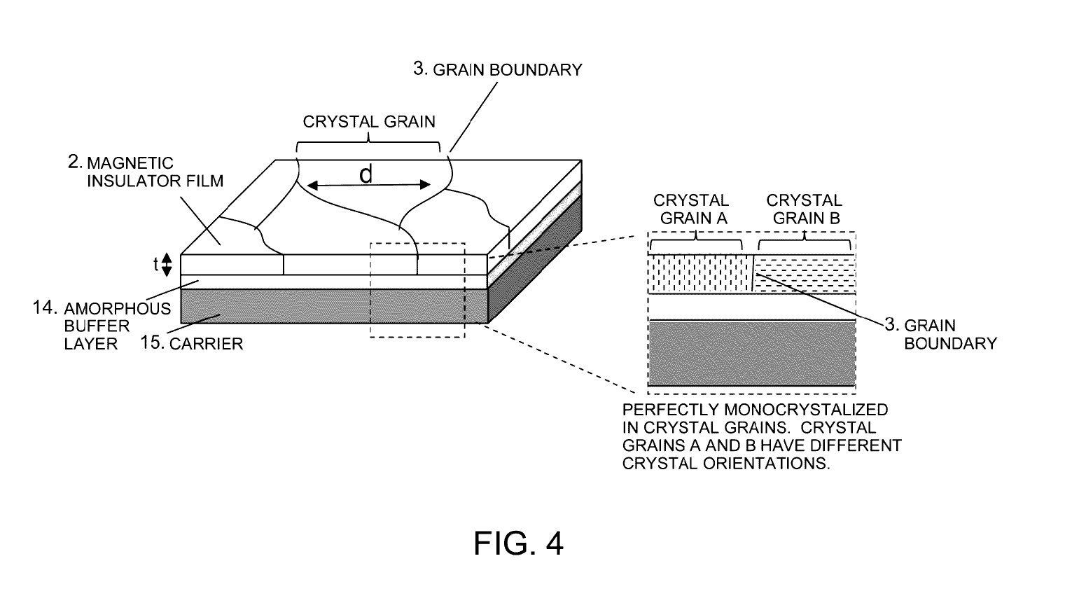

FIG. 4 is a perspective view showing a magnetic element according to a second embodiment of the present invention. In the second embodiment, an amorphous buffer layer 14 is formed on a surface (upper surface) of a carrier 15. Furthermore, a magnetic insulator film 2 is formed on the amorphous buffer layer 14.

In the second embodiment, the magnetic insulator film 2 has an atomic arrangement structure that is single-grained in a direction perpendicular to a film surface of the element.

The detail of the material for the carrier 15 does not matter as long as the carrier 15 supports the film. The carrier 15 is not limited to an insulator and may be made of a metal or a semiconductor material.

The amorphous buffer layer 14 serves as an underlay for depositing the magnetic insulator film 2. For example, an amorphous silicon layer on a surface of thermally oxidized silicon or an oxidized coating on a surface of a metal or the like may be used as the amorphous buffer layer 14.

As described above, when an oxide thin film grows on a surface of an oxide substrate, a growth initiation surface is likely to be determined uniquely by attachment of oxygen onto the surface of the substrate. Therefore, it is particularly preferable to use a combination of an amorphous oxide material for the amorphous buffer layer 14 and a magnetic oxide material for the magnetic insulator film 2 in order to direct the crystal structure of the magnetic insulator film 2 to a specific direction.

Such an application allows the magnetic insulator film 2 to be formed via the amorphous buffer layer 14 on various kinds of carriers 15 such as metals, semiconductors, and plastics. Accordingly, a thermoelectric conversion element, a spin information processing device, or the like can be formed and utilized on various kinds of carriers.

### Example 2

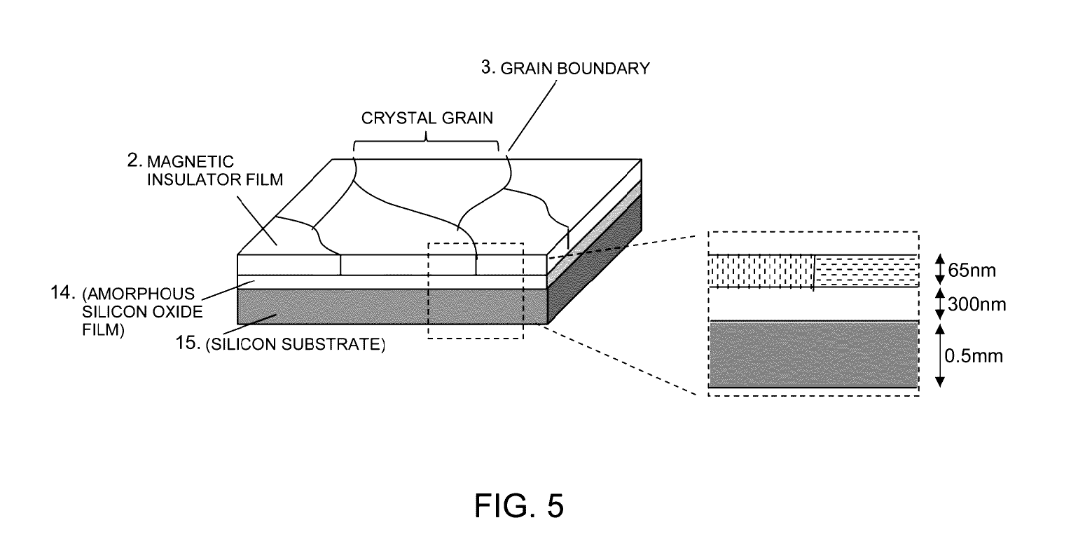

FIG. 5 shows Example 2 as a specific example of the second embodiment. In this example, a thermally oxidized silicon substrate having a thickness of about 0.5 mm is used for the amorphous buffer layer 14 and the carrier 15. In this substrate, an amorphous silicon oxide film (amorphous buffer layer 14) having a thickness of 300 nm is formed on a surface of a monocrystalline silicon substrate having a thickness of 0.5 mm. As with Example 1, bismuth substitution yttrium iron garnet (Bi:YIG with a composition of BiY₂Fe₅O₁₂) is used as the magnetic insulator film 2.

A Bi:YIG film is deposited by a metal organic decomposition method (MOD method). For example, a MOD solution manufactured by Kojundo Chemical Lab. Co., Ltd. is used for the Bi:YIG solution. Within this solution, a metal material with a proper mole fraction (Bi:Y:Fe=1:2:5) is dissolved in acetic ester at a concentration of 3%. This solution is applied onto the amorphous silicon oxide film (amorphous buffer layer 14) by a spin-coating method (with a rotation speed of 1,000 rpm and 30-second rotation). The amorphous silicon oxide film is dried with a hot plate of 150° C. for 5 minutes. Then the amorphous silicon oxide film is temporarily annealed at 550° C. for 5 minutes. Finally, the amorphous silicon oxide film is primarily annealed at a high temperature of 720° C. in an electric furnace for 14 hours. Thus, the Bi:YIG film having a film thickness of about 65 nm is formed on the amorphous silicon oxide film.

### Third Embodiment

### A Multilayered Magnetic Element

Conventional crystalline film structures are limited to underlying materials such as a crystal substrate that matches in lattice so that crystal grows on the crystal substrate. Therefore, it has been difficult to produce a multilayered form with a favorable crystalline film structure being maintained. In contrast, use of a magnetic crystalline film structure on a surface of an amorphous material according to the present invention allows a favorable crystalline film to be multilayered.

Thus, use of a multilayered magnetic crystalline film structure can achieve further enhancement of the capability of a thermoelectric conversion element or further enhancement of the integration of information processing/information recording devices.

### (Structure)

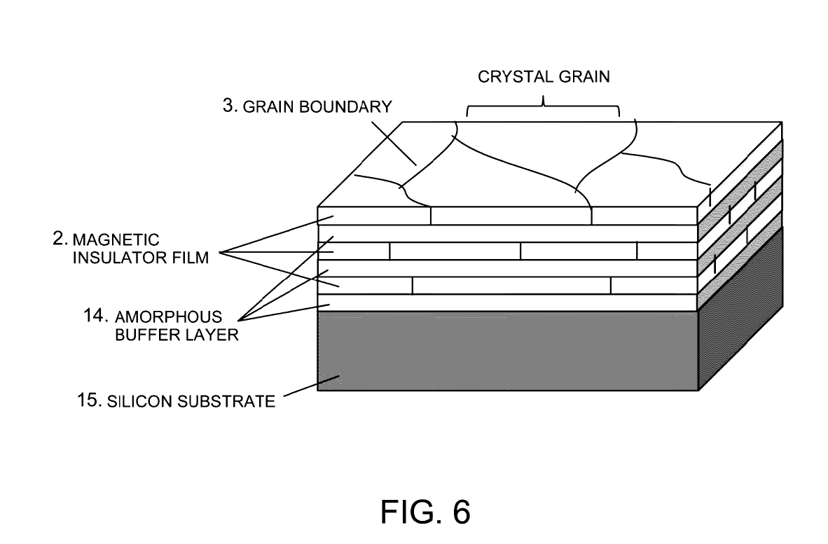

FIG. 6 is a perspective view showing a multilayered magnetic element according to a third embodiment of the present invention. In the third embodiment, a plurality of multilayer structures including a magnetic insulator film and an amorphous buffer layer are repeatedly stacked on the magnetic insulator crystalline film structure formed on the amorphous buffer layer illustrated in the second embodiment. Thus, a multilayered magnetic device is implemented.

### Example 3

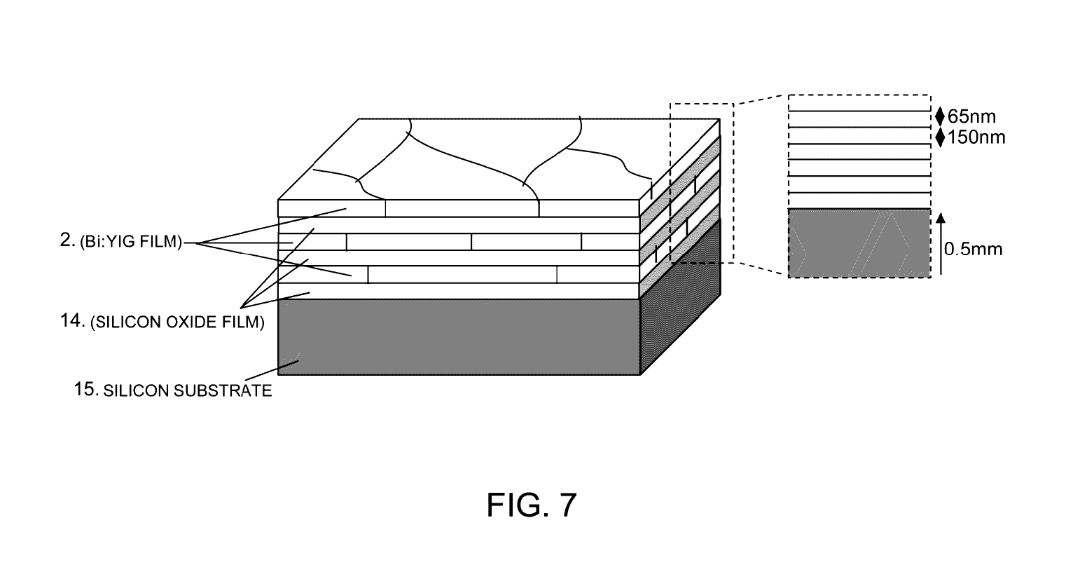

FIG. 7 shows a specific example of a multilayer structure. In this element, three layers having a structure of a Bi:YIG film and a silicon oxide film (SiO₂) are formed and stacked on a silicon substrate (carrier) 15. For producing this element, a silicon oxide film having a film thickness of 150 nm is deposited on a silicon substrate 15 having a thickness of 0.5 mm by sputtering. A Bi:YIG film having a film thickness of 65 nm is formed on the silicon oxide film by the same MOD method as in the first embodiment. This process is repeated three times to produce a multilayered magnetic element shown in FIG. 7.

### Fourth Embodiment

### A Thermoelectric Conversion Element

Next, a thermoelectric conversion element using a magnetic insulator crystalline film structure according to the first embodiment of the present invention will be described as a fourth embodiment of the present invention.

### (Structure)

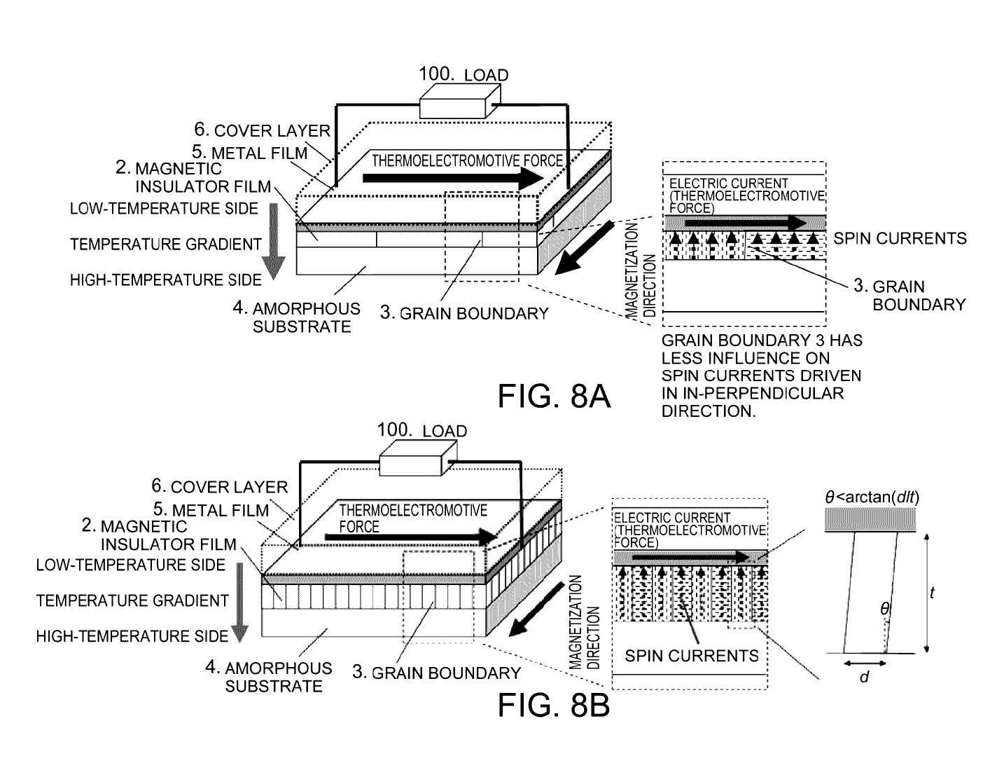

FIG. 8A is a perspective view showing a thermoelectric conversion element according to a fourth embodiment of the present invention. A thermoelectric conversion element is formed by a layered product having a metal film (conductive film) 5 formed on a magnetic insulator film 2 and an amorphous substrate 4 as in the first embodiment. The metal film 5 should preferably be covered with a cover layer 6 as indicated by broken lines in FIG. 8A. This also holds true for other embodiments described later. The essence of a thermoelectric conversion element using a columnar crystal magnetic material according to the present invention is that spin currents in the perpendicular-plane direction that are driven with the magnetic insulator film 2 by the spin Seebeck effects reach the metal film 5 without being scattered within the element. From this point of view, an inclination angle θ with respect to the perpendicular-plane direction of the grain boundary surface is preferably set for the grain size d and the film thickness t such that θ<arctan(d/t) in particular (FIG. 8B). For example, in a case of a columnar crystal grain structure where d=200 nm and t=1 μm, it is preferable to set the angle θ of the grain boundary surface such that θ<arctan(0.2)=11.3°.

As with the first embodiment, for example, magnetic oxide materials such as garnet ferrite or spinel ferrite may be applied to specific materials for the magnetic insulator film 2. Such a magnetic insulator crystalline film structure can be produced on various substrates by a wet process such as a metal organic decomposition method (MOD method) or a sol-gel method.

It is assumed that the magnetic insulator film 2 has magnetization in a direction parallel to the film surface. From a practical standpoint, it is preferable to use a material or structure having a coercive force for the magnetic insulator film 2. First, an external magnetic field is applied in a direction in a surface of the magnetic film that is perpendicular to a direction in which a thermoelectromotive force V is derived in the metal film 5, so that the magnetization direction is initialized. Thus, once the magnetization direction is initialized, the magnetic insulator film 2 holds spontaneous magnetization in this direction. Therefore, a thermoelectric conversion operation can be performed even in an environment of zero magnetic field. It is preferable to set the aforementioned coercive force to be at least 50 Oe in order to use the device stably in various electromagnetic field environments.

The metal film 5 includes a material that exhibits the spin-orbit interaction in order to obtain a thermoelectromotive force with use of the inverse spin Hall effect. Examples of such a material include metal materials that exhibit a relatively high degree of the spin-orbit interaction, such as Au, Pt, Pd, or, Ir and alloys containing such metals. The same effects can be attained when a general metal film material, such as Cu, is doped with a material of Au, Pt. Pd, Ir, or the like at only about 0.5% to about 10%.

Such a metal film 5 is deposited by a sputtering method, a vapor deposition method, or the like. Furthermore, an ink-jet method, a screen printing method, or the like may be used for production.

Here, in order to convert spin currents into electricity with a high efficiency without any wastes, it is preferable to set the thickness of the metal film to be at least the spin diffusion length of the metal material. For example, it is preferable to set the thickness of the metal film to be at least 50 nm if the metal film is made of Au. It is preferable to set the thickness of the metal film to be at least 10 nm if the metal film is made of Pt.

In a sensing application that uses the thermoelectric effect as a voltage signal, a larger thermoelectromotive force signal is likely to be obtained with a higher sheet resistance of the metal film 5. Therefore, it is preferable to set the thickness of the metal film to be equal to about the spin diffusion length of the metal material. For example, it is preferable to set the thickness of the metal film to be in a range of about 50 nm to about 150 nm if the metal film is made of Au. It is preferable to set the thickness of the metal film to be in a range of about 10 nm to about 30 nm if the metal film is made of Pt.

### (Explanation of Operation)

When a temperature gradient is applied to a thermoelectric conversion element having such a structure in a direction perpendicular to the plane, currents of angular momentum (spin currents) are induced in the direction of this temperature gradient by the spin Seebeck effect in the magnetic insulator film 2.

Those spin currents generated in the magnetic insulator film 2 flow into the adjacent metal film 5. The spin currents are converted into an electric current (electromotive force) by the inverse spin Hall effect in the metal film 5. Thus, a thermoelectric conversion effect is exhibited.

Because of the symmetry based upon the spin Seebeck effect and the inverse spin Hall effect, a thermoelectromotive force in the metal film 5 is generated in a direction perpendicular to both of a direction in which a temperature gradient is applied and a magnetization direction of the magnetic insulator film 2, i.e., a direction of a vector product. When the direction of magnetization or a temperature gradient is inversed, the sign of the thermoelectromotive force is inversed.

There has been described an embodiment in which a temperature gradient is applied in a direction perpendicular to a surface of the magnetic insulator film. However, as reported in Non-Patent Literature 2, thermoelectric conversion may be performed by a method of providing an element structure in which a metal film is arranged at an end of a magnetic insulator film and applying an in-plane temperature gradient parallel to the magnetic insulator film to generate an electromotive force in the metal film.

### (Use of a Thermoelectric Conversion Element)

When electric power is actually generated with use of a thermoelectric conversion element having a stacked structure including a substrate, a magnetic insulator film, and the like as described above, a temperature difference is applied to the element while one surface of the element is used as a high-temperature side, whereas the other surface of the element is used as a low-temperature side. For example, one surface of the element (the high-temperature side) is brought close to a heat source having a high temperature and is thus set at a temperature T_{H}. The other surface of the element (the low-temperature side) is air-cooled or water-cooled as needed and set at a temperature T_{L}. Thus, a temperature difference ΔT=T_{H}−T_{L} is generated.

At that time, if the temperature of the magnetic insulator portion exceeds the Curie temperature T_{C} in a thermoelectric converter element according to the present invention, the spin Seebeck effect is impaired. As a result, an operation for power generation cannot be performed. Therefore, when thermoelectric power generation is performed with use of the thermoelectric conversion element shown in FIG. 8A, it is preferable to use a surface located away from the magnetic insulator film 2 (the lower surface of the amorphous substrate 4 in FIG. 8A) as a high-temperature side and use a surface located near the magnetic insulator film 2 (the upper surface of the metal film 5 in FIG. 8A) as a low-temperature side.

In order to ensure the operation for thermoelectric power generation by the aforementioned temperature difference application method, at least the low-temperature side should not exceed the Curie temperature of the magnetic insulator such that T_{L}<T_{C}. However, the high-temperature side may exceed the Curie temperature if the low-temperature side can properly be cooled so as to meet the above conditions. Therefore, the conditions may be such that T_{L}<T_{C}<T_{H}. Use of such a temperature difference application method makes it easier to apply a thermoelectric conversion element of the present invention to a high-temperature region.

### Advantageous Effects

As described above, when a columnar crystal structure is used in a thermoelectric conversion element driven by spin currents, spin currents thermally driven in a perpendicular-plane direction within a magnetic film can propagate without being scattered to a large extent. Therefore, the spin currents can efficiently derived as electric power in the metal film. If any grain boundary surface should be present in the vertical direction of FIG. 8A (in a direction perpendicular to the film surface), it have little effect of blocking perpendicular-plane spin currents. Accordingly, the thermoelectric performance is not greatly degraded.

A thermoelectric device using spin currents is advantageous in that it has a simpler configuration as compared to a conventional thermoelectric device using a thermocouple connection structure and also has a convenient scaling law that a higher output of thermoelectric generation can readily be produced with a larger area. This scaling law of thermoelectric generation is more specifically described below.

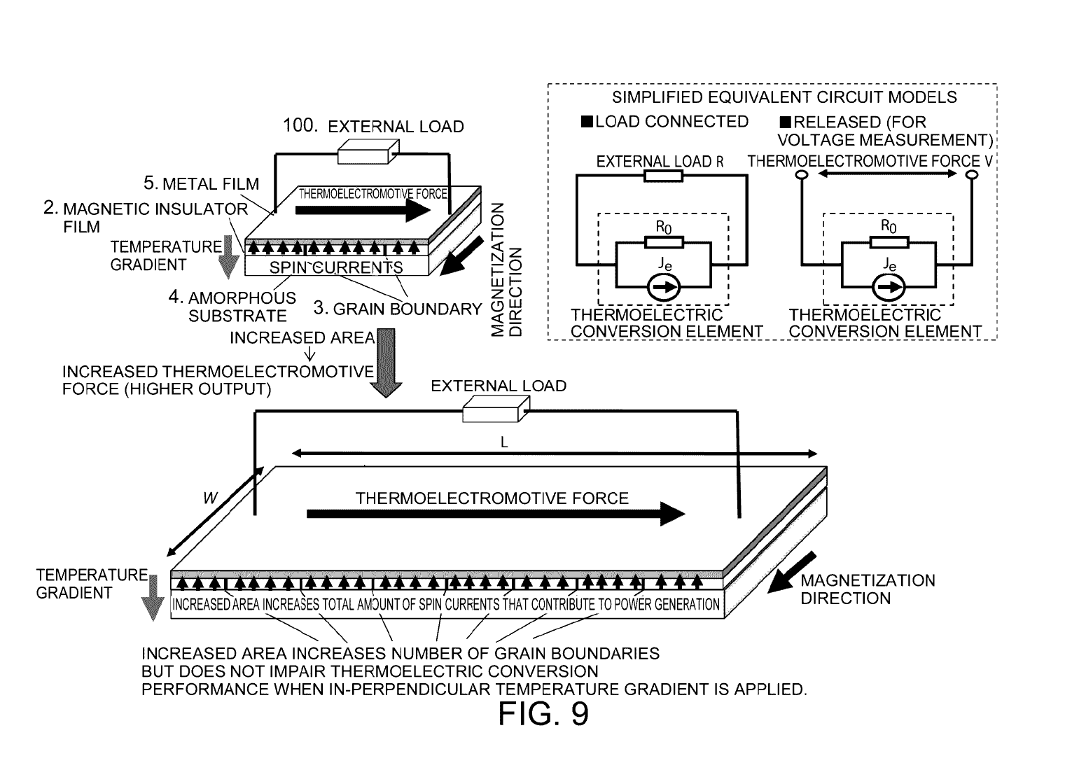

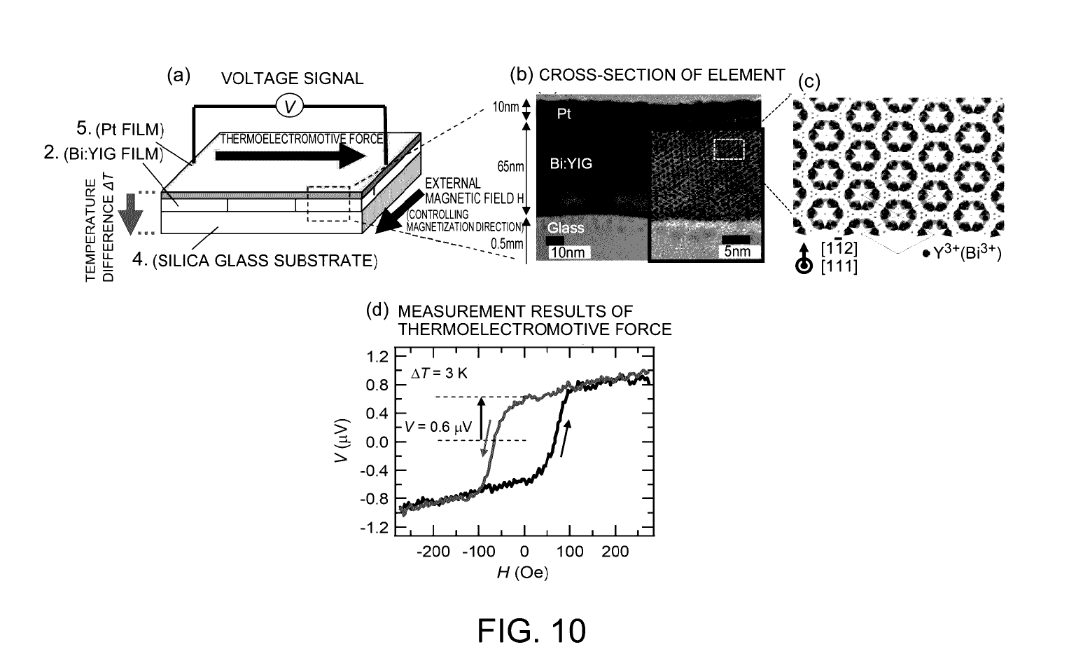

In a thermoelectric conversion element shown in FIG. 9, the length of the metal film 5 in a direction parallel to a direction in which a thermoelectromotive force is generated is defined by L, and the length of the metal film 5 in a direction perpendicular to the direction in which a thermoelectromotive force is generated is defined by W. At that time, if L is increased while W is held constant, a thermoelectromotive force V (an output voltage at the time when output terminals are opened without any load being connected as shown in (d) of FIG. 10, which will be described later) and an internal resistance R₀ of the thermoelectric conversion element increase in proportion to L (R₀∝L). If W is increased while L is held constant, the internal resistance R₀ decreases in inverse proportion to W while a thermoelectromotive force V does not change.

The above relationship provides the following relationships.

V∝L,R₀∝L/W

From those results, assuming that the resistance (external resistance R) of a load 100 being externally connected is properly matched in impedance with respect to the internal resistance R₀ of the thermoelectric conversion element, an optimum electric power W (∝V²/R₀∝L×W) that can be derived with an external load is substantially in proportion to the area of the thermoelectric conversion element S=L×W.

From the above study, in a thermoelectric conversion element using spin currents according to the fourth embodiment, more spin currents flow into a metal film and contribute to power generation as an area of the element (length×width) is increased. As a result, a larger electric energy can be obtained. As shown at the lower part of FIG. 9, the number of grain boundaries increases in the magnetic insulator film as the area of the thermoelectric conversion element increases. However, those grain boundaries do not greatly contribute to scattering of spin currents thermally driven in the perpendicular-plane direction and, therefore, do not impair the thermoelectric conversion performance.

FIG. 9 shows equivalent circuit models at the time of load connection and release (for voltage measurement) on its right side.

Crystal having such a structure can be deposited by a coating-based process such as an MOD method or a sol-gel method as illustrated in the aforementioned Example 1 and the following Example 4. Thus, a large-area device can readily be implemented by a manufacturing process such as a highly productive spin-coating deposition.

In this manner, a thermoelectric conversion element having a structure of “a columnar crystalline film and an amorphous substrate” according to the present invention can avoid performance degradation caused by crystal imperfection, also allows a large-area implementation on a low-cost substrate, and is thus a particularly preferable thermoelectric conversion structure that can achieve both of performance and low cost.

### Example 4

Next, Example 4 will be described as a specific example of the fourth embodiment with reference to FIG. 10.

The figure (a) of FIG. 10 shows a specific material and structure of a thermoelectric conversion element. A silica glass substrate having a thickness of 0.5 mm is used as an amorphous substrate 4. An yttrium iron garnet (Bi:YIG) film in which Bi has been substituted for part of the Y sites is used as a magnetic insulator film 2. Pt is used as a metal film 5. The thickness of the silica glass substrate is 0.5 mm, the thickness of the Bi:YIG film is 65 nm, and the thickness of the Pt film is 10 nm.

The Bi:YIG film is deposited by a metal organic decomposition method (MOD method) as with Example 1. A MOD solution manufactured by Kojundo Chemical Lab. Co., Ltd. is used. Within this solution, raw metal materials having a proper mole fraction (Bi:Y:Fe=1:2:5) are dissolved in acetic ester at a concentration of 3%. This solution is applied onto the silica glass substrate by a spin-coating method (at a revolving speed of 1.000 rpm for 30 seconds). The silica glass substrate is dried with a hot plate of 150° C. for 5 minutes. Then the silica glass substrate is temporarily annealed at 550° C. for 5 minutes. Finally, the silica glass substrate is primarily annealed at a high temperature of 720° C. in an electric furnace for 14 hours. Thus, a Bi:YIG film having a film thickness of about 65 nm is formed on the silica glass substrate.

A Pt film having a film thickness of 10 nm is deposited on the Bi:YIG film by a sputtering method.

The figures (b) and (c) of FIG. 10 show the results of evaluation with a cross-sectional TEM on the crystal structure of this film and an arrangement diagram corresponding to the crystal structure. As with the first embodiment, it has been confirmed that a Bi:YIG film close to monocrystal was formed on a silica glass substrate as an amorphous substrate. In the thermoelectric conversion element of Example 4, spin currents thermally induced in the Bi:YIG film should be derived from the Pt film. The Bi:YIG film has a crystal structure in which orientation has been aligned up to its end (near the interface). This favorable interface structure between Pt and Bi:YIG allows a thermoelectric conversion function to operate.

The thermoelectromotive force performance of this thermoelectric conversion element was evaluated by a method shown in FIG. 10. In this example, a voltage (thermoelectromotive force) V between terminals of the metal film 5 was measured in a state in which a temperature difference ΔT=3 K was applied between an upper side and a lower side of the thermoelectric conversion element, i.e., an upper surface of the Pt film and a lower surface of the silica glass substrate. In this experiment, measurement was performed with an external magnetic field H (Oe) being applied for experimental validation of thermoelectric conversion symmetry based upon the spin Seebeck effect. As described above, a thermoelectromotive force generated in the Pt film is directed to a direction corresponding to a vector product of a temperature gradient direction and a magnetization direction of the Bi:YIG film. Therefore, when the magnetization of the Bi:YIG film is inversed by the external magnetic field H, the sign of the thermoelectromotive force V is also inversed.

The figure (d) of FIG. 10 shows the measurement results with this setup. The measurement results of the thermoelectromotive force V are plotted with the horizontal axis of the external magnetic field H. It is clearly illustrated that the sign of the thermoelectromotive force V was inversed by changing the sign of the external magnetic field H so as to inverse the magnetization direction. A thermoelectromotive force V=about 0.6 (μV) was measured with a temperature difference ΔT=3 K. From the magnetic field at which the sign of V was inversed, it is shown that the thermoelectric conversion element had a coercive force of at least 50 Oe and could operate stably in practice.

The Bi:YIG film formed on the silica glass substrate at this time had a coercive force. Therefore, the dependency of the thermoelectromotive force V on the external magnetic field H demonstrates hysteresis. Specifically, once the element is magnetized in one direction by an external magnetic field, it exhibited a finite thermoelectromotive force even though the magnetic field H returned to zero. Thus, with this principle, once the magnetization direction of the element is first initialized by an external magnetic field or the like (magnetized in a direction substantially perpendicular to a direction in which a thermoelectromotive force is derived), a thermoelectromotive force can be generated stably by spontaneous magnetization of the magnetic insulator film 2 even in an environment where the magnetic field is zero.

### (Increase of the Thermoelectric Effect Due to the Phonon Drag Effect of the Spin Currents)

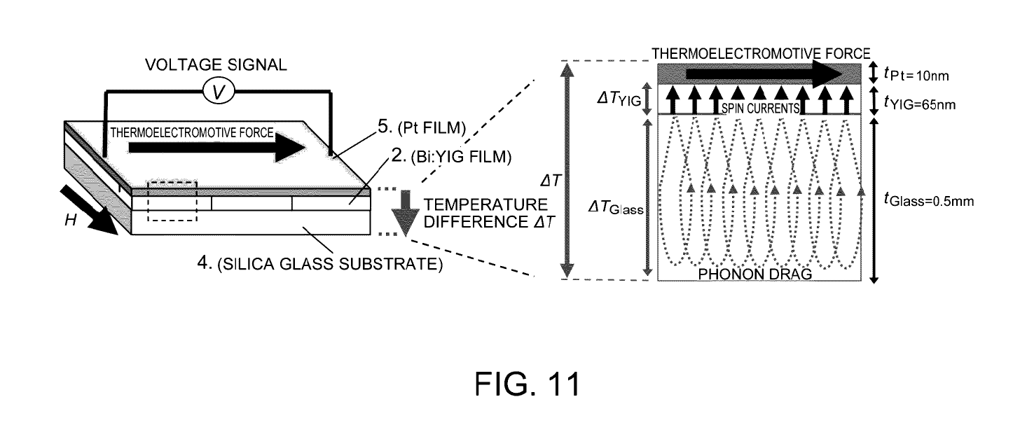

As shown in FIG. 11, in the experiments of the aforementioned Example 4, a temperature difference ΔT=3 K was applied between the upper surface and the bottom surface of the thermoelectric conversion element, and a thermoelectromotive force was measured. The film thickness of the magnetic insulator (Bi:YIG) film on the silica glass substrate having a thickness of 0.5 mm was as thin as 65 nm. Therefore, a temperature difference ΔT_{YIG} applied to a magnetic insulator portion (film thickness portion of Bi:YIG) in which spin currents are thermally driven is supposed to be about several mK even at the highest estimate and to be extremely small. Nevertheless, according to Example 4 of the present invention shown in FIG. 10, the thermoelectromotive force was measured on the order of μV. This experiment result showing a relatively large thermoelectromotive force is not readily explained merely by the spin current thermoelectric effect in the metal film 5 and the magnetic insulator film 2. Thus, this experiment result strongly suggests contribution of “phonon drag effect,” in which the thermoelectric effect is enhanced through interaction with phonons in the substrate.

The phonon drag refers to a phenomenon in which spin currents in a structure of a metal film and a magnetic insulator film interact non-locally with phonons of an overall element including a substrate (Non-Patent Literature 4). In consideration of this phonon drag process, spin currents in a very thin film as in Example 4 are sensitive to a temperature distribution in a substrate that is much thicker than the thin film, through the non-local interaction with the phonons. Therefore, the effective thermoelectric effects greatly increase.

Specifically, not only the temperature difference ΔT_{YIG} applied to a thin magnetic insulator (film thickness portion of Bi:YIG), but also the temperature difference ΔT_{Glass} applied to a thick substrate contributes to the thermal driving of the spin currents. As a result, a larger thermoelectromotive force is generated in the metal film (Pt film).

While validation of the fundamental principle of such a phonon drag effect has been reported, there have been no specific proposals for methods of designing large-area and low-cost thermoelectric devices using this effect. In the structure of a metal film and a magnetic insulator film according to the present invention, use of this phonon drag effect allows a thermoelectric conversion device to be mounted merely by depositing a thin structure of a metal film and a magnetic insulator film that has a thickness of 100 nm or less on an inexpensive amorphous substrate. Therefore, costs for raw materials and other manufacturing costs can remarkably be reduced as compared to a case where a bulk magnetic material or the like is used. In addition, coating is used for a production process of a magnetic insulator film as in Example 4. Accordingly, large-area devices can be manufactured with high productivity.

Most of amorphous substrate materials can be produced at cost per volume that is not more than 1/10 of those of magnetic insulator film materials such as YIG. Therefore, when a low-cost thermoelectric element using the phonon drag effect is designed, it is preferable to set the thickness (t_{YIG}) of the magnetic insulator film to be 1/10 or less of the total thickness (t_{Ptv}+t_{YIG}+t_{Glass}), where the thickness of the electrode (metal film) (t_{Pt}) and the thickness of the amorphous substrate (t_{Glass}) have been added to the thickness (t_{YIG}) of the magnetic insulator film.

However, the experiment results suggest that high thermoelectric performance cannot be obtained if the thickness (t_{YIG}) of the magnetic insulator film is excessively small. Therefore, t_{YIG} should preferably be at least 50 nm.

### (Comparison Between the Example and the Prior Art as to a Magnetic Insulator Film Structure)

Attempts have heretofore been made to produce a magnetic insulator material on an amorphous substrate. However, any high-quality film close to monocrystal as in the above examples has never been produced on an amorphous substrate. Furthermore, any columnar crystalline film in which all grain boundary surfaces were perpendicular to the film surface has never been found distinctly so far.

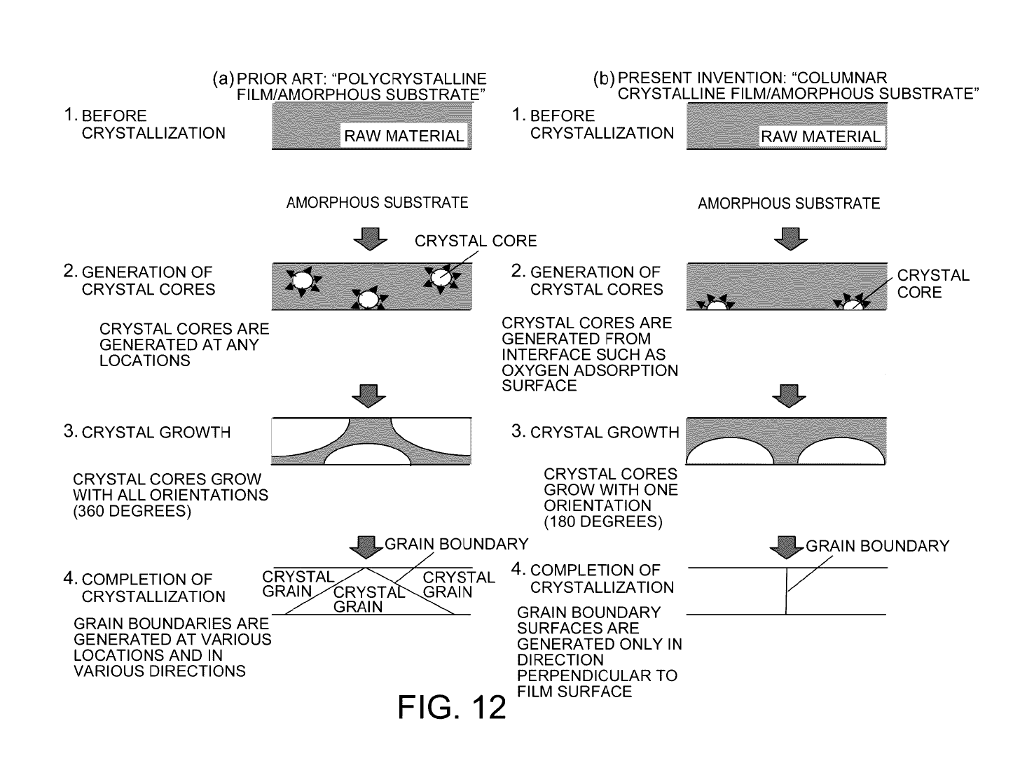

There are two primary reasons why such a crystalline film could not be produced. (1) Since an amorphous substrate having no crystal periodicity does not serve as a template for film growth, stable crystal is unlikely to be formed on an insulator film having no flexibility in movement of electrons or the like. (2) If crystal growth should start with cores located at certain points of a film, crystal grains that grow from a plurality of cores through 360° conflict with each other. As a result, grain boundaries are generated at various locations and in various directions (see the figure (a) of FIG. 12).

In contrast, it is supposed that a favorable crystalline film as shown in FIG. 10 was formed for the following reasons: (1) Oxygen is preferentially adsorbed on a surface of an oxide material such as silica glass, which is amorphous. The adsorbed oxygen serves as an effective growth core that defines crystal orientation at the time of the initial growth. (2) Crystal growth progresses in one direction (primarily in a direction of 180° from the lower to the upper) only from limited growth cores on an interface of the substrate under a proper annealing temperature, an annealing time, and an annealing atmosphere corresponding to a material solution. Therefore, there is a low probability that grain boundaries are generated by conflict of crystal grains. If grain boundaries should be generated, they are fixed on a surface perpendicular to the film (see the figure (b) of FIG. 12).

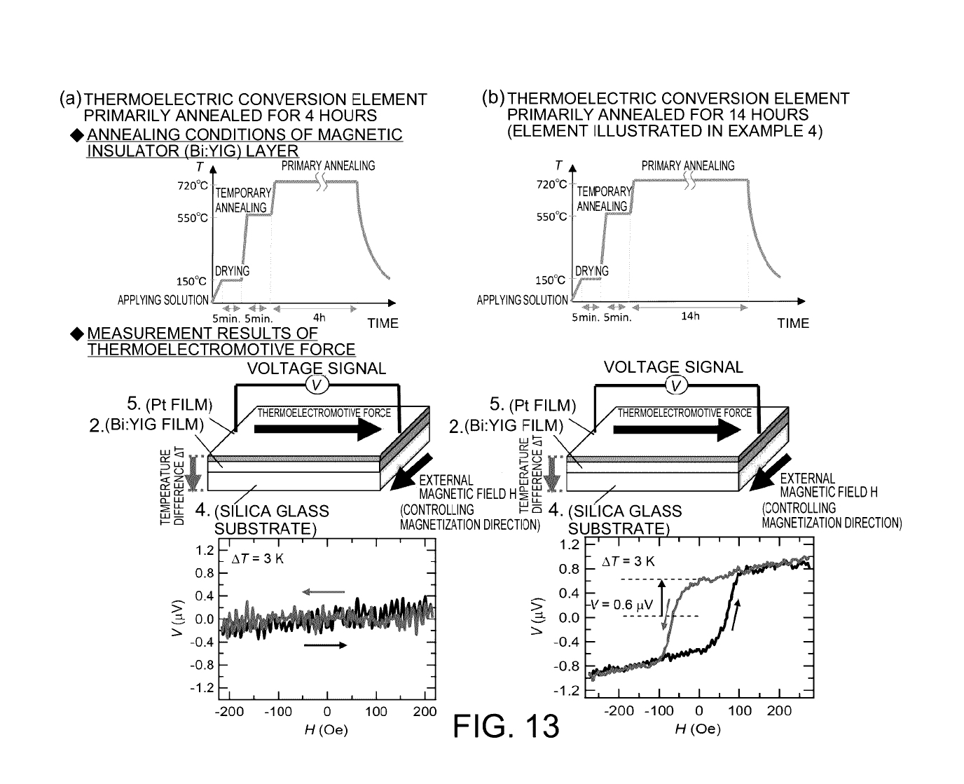

For example, the MOD method disclosed in Patent Literature 1 suggests epitaxial production of a high-quality magnetic garnet crystalline film on a GGG monocrystalline substrate. Nevertheless, a film on an amorphous substrate has lowered crystal quality. The results of the film quality evaluation with an X-ray suggest that a film on an amorphous substrate is polycrystal having many boundaries. In fact, as shown in the figure (a) of FIG. 13, the inventors followed the manufacturing method (conditions of sintering time) disclosed in Patent Literature 1. The primary annealing time for the MOD deposition was shortened to 4 hours to form a magnetic insulator film. The same metal film as in Example 4 was stacked on the magnetic insulator film so as to form a thermoelectric conversion element. In such a case, the magnetic insulator film had low crystal quality, and no clear thermoelectric conversion signal was found. On the other hand, as shown in the figure (b) of FIG. 13, a favorable magnetic insulator crystalline film was formed by primary annealing for 14 hours, and a thermoelectric conversion element could be operated.

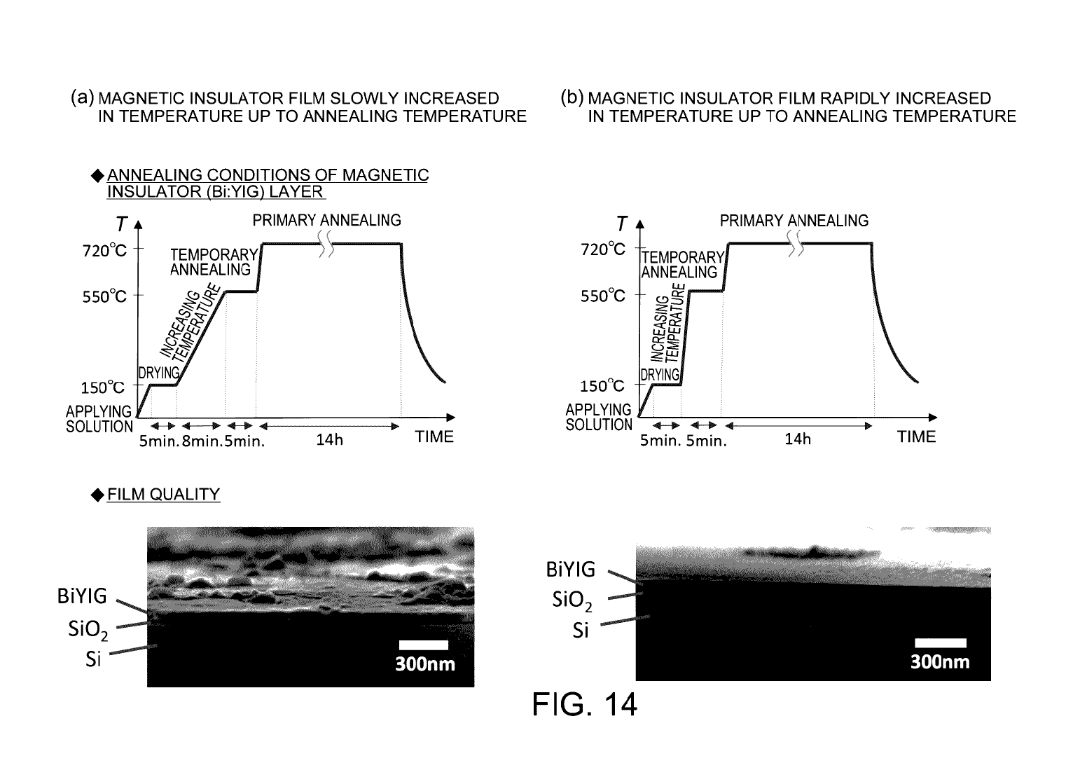

Furthermore, a series of deposition and evaluation experiments have revealed that the crystal quality of a magnetic insulator film greatly varies depending upon a heating temperature of temporary annealing or primary annealing for MOD deposition. For example, observation with a scanning electron microscope (SEM) have revealed that the film quality of a magnetic insulator (Bi:YIG) greatly varied depending upon a speed to increase of the temperature to a temporary annealing temperature (550° C.) (a period spent for temperature increase) after coating and drying an MOD solution. Specifically, as shown in the figure (a) of FIG. 14, when the temperature was increased to a temporary annealing temperature in about 8 minutes, only a low-quality film having irregularities at a high density on a surface thereof was obtained as shown in the figure modeling a SEM photograph (the lower of the figure (a) of FIG. 14). A thermoelectric conversion operation using this film could not be confirmed. In contrast, under deposition conditions shown in the figure (b) of FIG. 14, in which the temperature was rapidly increased to a temporary annealing temperature within 30 seconds, a favorable magnetic insulator crystalline film was obtained as shown in the figure modeling a SEM photograph (the lower of the figure (b) of FIG. 14). A thermoelectric conversion operation using this magnetic insulator crystalline film was successfully validated. As a specific method of rapidly increasing the temperature, a sample was introduced into an electric furnace preheated to a temporary annealing temperature (550° C.). With this method, the sample could rapidly be heated to about the temporary annealing temperature within 3 seconds. Furthermore, it has been confirmed that the sample reached a steady state at the temporary annealing temperature within 30 seconds or less. In this example, a thermally oxidized silicon substrate in which an amorphous silicon oxide film of 20 nm was formed on a surface of silicon was used as the substrate.

As shown by this series of experiment results, even if a proper material solution is used, a favorable magnetic insulator crystalline film and thermoelectric conversion element cannot be obtained unless the film is formed under optimal deposition conditions. According to the present invention, a period of time spent for temperature increase is shortened as shown in the figure (b) of FIG. 14. Thus, growth cores are generated at limited locations on a surface of a substrate. As a result, it is suggested that a favorable crystalline film is generated with less grain boundaries. At the same time, the results of FIG. 13 suggest that, under such conditions to limit generation of growth cores, crystallization of the entire film is not fully completed unless primarily annealing is conducted for a sufficiently long period of time. Specifically, the validation of a thermoelectric conversion operation on a silica glass substrate shown in FIG. 10 means that crystal growth occurred in one direction from growth cores on an interface of the substrate by using a proper annealing temperature profile and annealing time according to this study.

In a case of a thermoelectric conversion element formed on a glass substrate as in Example 4, cost reduction and area enlargement are facilitated. Therefore, such a thermoelectric conversion element can be applied to power generation using temperature differences at a window or the like between the inside and the outside of a room and to a display and the like.

### Fifth Embodiment

### Another Example of a Thermoelectric Conversion Element

Next, another example of a thermoelectric conversion element according to a fifth embodiment of the present invention will be described below.

### (Structure)

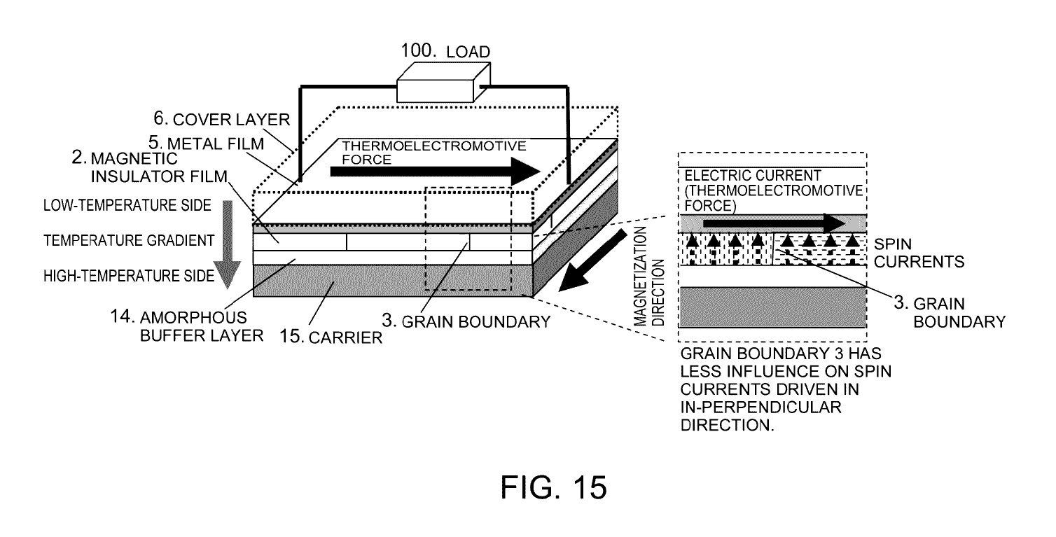

FIG. 15 is a perspective view of a thermoelectric conversion element according to a fifth embodiment according to the present invention. As with the second embodiment, an amorphous buffer layer 14 and a magnetic insulator film 2 are formed in order on a carrier 15. A metal film 5 is formed on the magnetic insulator film 2 for deriving generated power caused by a thermal gradient.

The same material as described in the second embodiment may be used for the amorphous buffer layer 14. The same material and film thickness as described in the fourth embodiment may be used for the metal film 5.

### Example 5

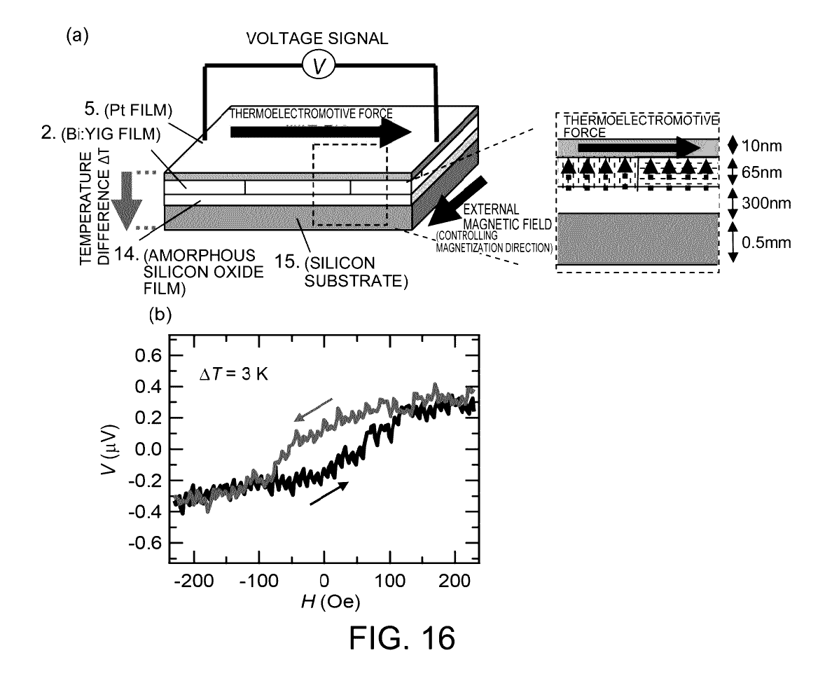

FIG. 16 shows Example 5 as a specific example of the fifth embodiment. A thermally oxidized silicon substrate having a thickness of about 0.5 mm is used for the amorphous buffer layer 14 and the carrier 15. In this substrate, an amorphous silicon oxide film of 300 nm is formed on a surface of monocrystalline silicon having a thickness of 0.5 mm. As with Example 2, bismuth substitution yttrium iron garnet (Bi:YIG with a composition of BiY₂Fe₅O₁₂) is used as the magnetic insulator film 2.

As with Example 2, a Bi:YIG film is deposited by a metal organic decomposition method (MOD method). Within this solution, a metal material with a proper mole fraction (Bi:Y:Fe=1:2:5) is dissolved in acetic ester at a concentration of 3%. This solution is applied onto the amorphous silicon oxide film by a spin-coating method (with a rotation speed of 1,000 rpm and 30-second rotation). The amorphous silicon oxide film is dried with a hot plate of 150° C. for 5 minutes. Then the amorphous silicon oxide film is temporarily annealed at 550° C. for 5 minutes. Finally, the amorphous silicon oxide film is primarily annealed at a high temperature of 720° C. in an electric furnace for 14 hours. Thus, a Bi:YIG film having a film thickness of about 65 nm is formed on the amorphous silicon oxide film. A Pt film having a film thickness of 10 nm is deposited as the metal film 5 on the Bi:YIG film.

As with Example 4, a thermoelectric conversion operation was examined. The figure (b) of FIG. 16 shows the results. As with the figure (b) of FIG. 10, generation of the thermoelectromotive force and fundamental symmetry of the thermoelectric conversion were validated

### (Another Implementation Configuration of Example 5)

Such a thermoelectric conversion film structure may be formed not only on the aforementioned insulator or semiconductor, but also on a carrier made of a metal material.

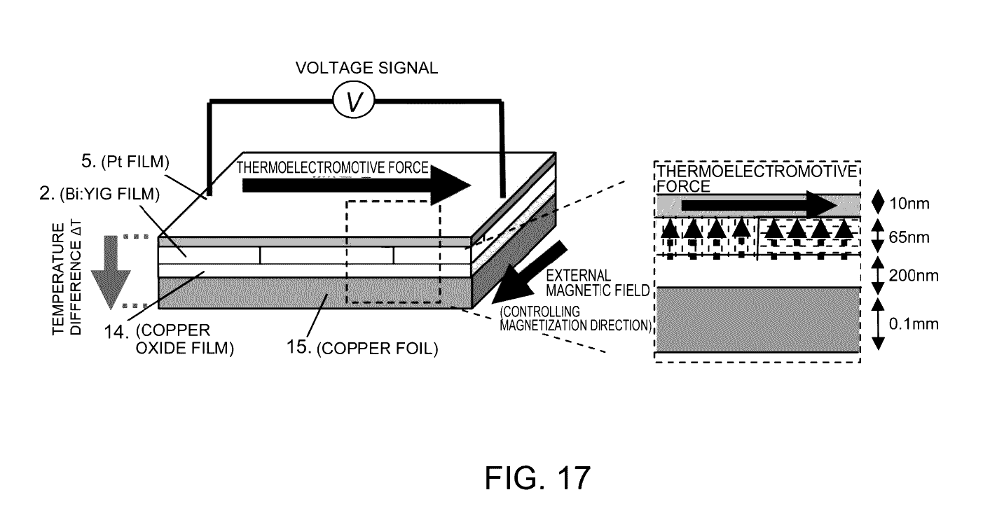

In a thermoelectric conversion element shown in FIG. 17, copper foil having a thickness of 0.1 mm is used as a carrier 15. The copper foil is heated under an atmospheric environment at 100° C. for 30 minutes so as to form a copper oxide film (oxide film) having a thickness of about 200 nm on a surface thereof. Then a Bi:YIG layer and a Pt layer are sequentially deposited on the copper foil by the same method as described above, so that a thermoelectric conversion element is implemented.

In this manner, a thermoelectric conversion film structure may be implemented on a metal oxide film/a metal carrier and may be applied to industrial structures or housings of various devices.

### Sixth Embodiment

### A Thermoelectric Conversion Element Having a Multilayered Magnetic Crystalline Film Structure

In a thermoelectric conversion element shown in the above embodiment, a thermoelectromotive force can be obtained by applying, to a structure of a metal film and a magnetic insulator film, a temperature gradient perpendicular to a film surface.

If the metal film and the magnetic insulator film can be stacked with multiple layers, thermoelectromotive forces can be derived from a plurality of metal films. Therefore, more efficient thermoelectric conversion can be achieved. However, underlying materials that can form a favorable magnetic insulator crystalline film have been limited in the prior art. Accordingly, no high-performance multilayered thermoelectric conversion element using spin currents has been realized.

In contrast, as described in the third embodiment, a favorable magnetic crystalline film can be grown with use of an underlay of an amorphous material according to the present invention. Therefore, a structure of a metal film and a magnetic insulator film can be multilayered with use of amorphous buffer layers.

### (Structure)

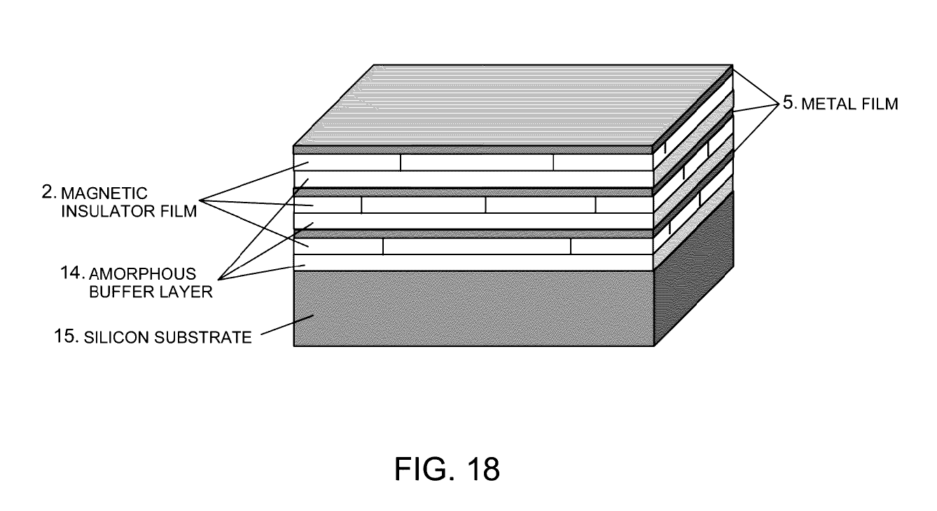

FIG. 18 is a perspective view of a multilayered thermoelectric conversion element according to a sixth embodiment of the present invention. In the sixth embodiment, metal films 5 and magnetic insulator films 2, and amorphous buffer layers 14 are additionally stacked on the structure illustrated in the fifth embodiment, so that a multilayered thermoelectric conversion device is implemented.

If a temperature gradient is applied to this thermoelectric conversion device in the perpendicular-plane direction, a thermoelectromotive force is generated in the in-plane direction in each of the metal films 5 according to the operation principle described in the fourth embodiment. Therefore, when those thermoelectromotive forces are effectively added up by electrically connecting those metal films 5 in series or the like, a higher output can be obtained. Thus, more efficient thermoelectric conversion element can be achieved as compared to the thermoelectric conversion element of the fifth embodiment.

### Example 6

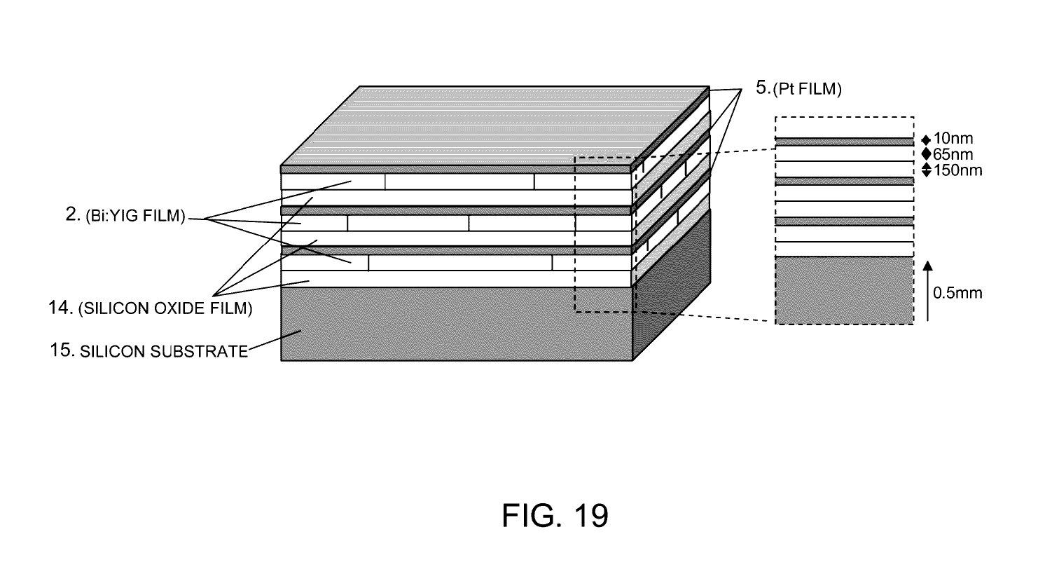

FIG. 19 shows Example 6 of a thermoelectric conversion element having a multilayered structure as a specific example of the sixth embodiment. In this element, three layers of a structure including a Pt film, a Bi:YIG film, and a silicon oxide film (SiO₂) are stacked on a silicon substrate 15.

For producing this element, a silicon oxide film (amorphous buffer layer 14) having a film thickness of 150 nm is deposited on a silicon substrate 15 having a thickness of 0.5 mm by sputtering. A Bi:YIG film (magnetic insulator film 2) having a film thickness of 65 nm is formed on the silicon oxide film by the same MOD method as in the first embodiment. Finally, a Pt film (metal film 5) having a film thickness of 10 nm is deposited by sputtering. This process is repeated three times to produce a thermoelectric conversion element shown in FIG. 19.

### Seventh Embodiment

### Direct Implementation of a Thermoelectric Function by Thermoelectric Coating

Next, “thermoelectric coating,” in which thermoelectric conversion function is implemented directly on any heat source, will be described as a seventh embodiment of the present invention.

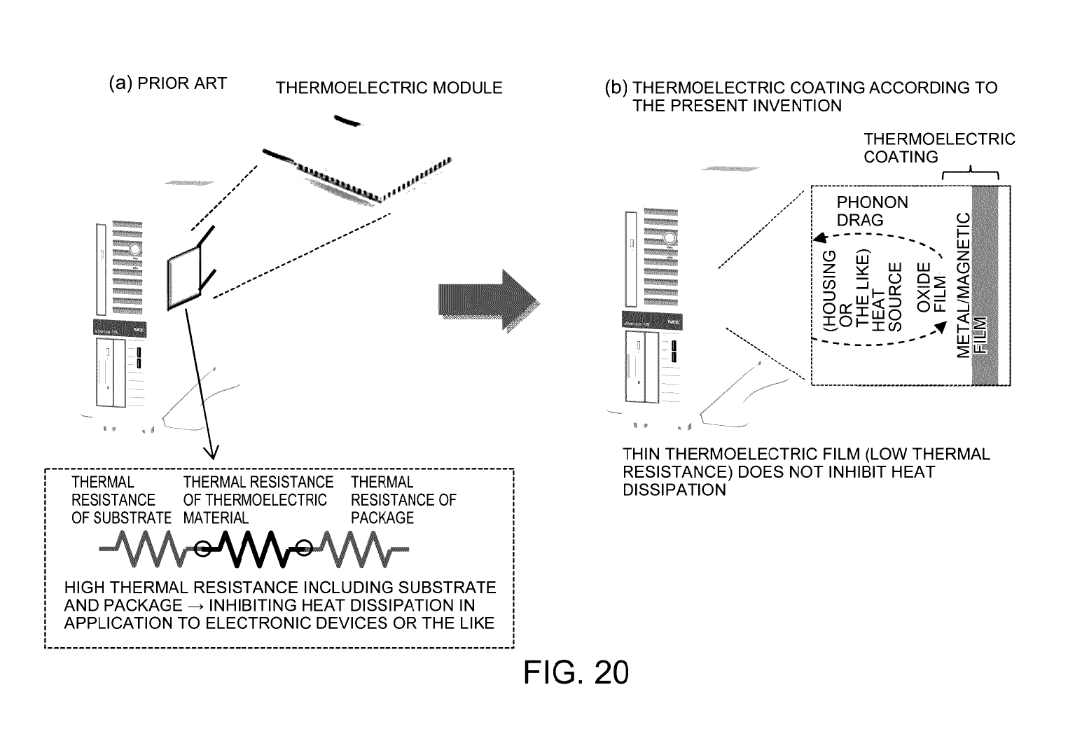

In a case of conventional thermoelectric conversion based upon thermocouples, a number of thermocouples are connected on a substrate, and the whole structure is packaged so as to implement a “thermoelectric conversion module.” One side of this thermoelectric conversion module is attached onto a surface of a high-temperature heat source or the like to generate a temperature difference so as to perform thermoelectric power generation (the figure (a) of FIG. 20). With such a packaging method, however, the thermal resistance of the entire thermoelectric conversion module including the substrate and the package becomes high. Therefore, if a thermoelectric conversion module having such a high thermal resistance is applied to a hot surface that needs heat dissipation, such as LSIs or electronic devices, then it greatly inhibits heat dissipation, thereby causing malfunction of the electronic device or the like.

In contrast, for “thermoelectric coating” according to the seventh embodiment, an oxide film is formed on a surface of any heat source and is then coated directly with a thermoelectric conversion film structure using spin currents as shown in the figure (b) of FIG. 20. In this case, thermoelectric power generation can be performed merely by adding a thin thermoelectric film (low thermal resistance) onto a surface of a heat source without use of a package or a substrate. Accordingly, inhibition of heat dissipation by the thermoelectric conversion element exerts less adverse influence. Furthermore, as described later, heat (phonon) energy at a heat source is expected to be derived non-locally by a thermoelectric film due to the phonon drag effect. Therefore, this thermoelectric conversion module can be introduced into various electronic devices.

Additionally, the following useful thermal power generation functions can be achieved as compared to conventional thermoelectric conversion.

(1) The efficiency of using heat is high because heat is derived directly from a high-temperature heat source without use of a package or a substrate.

(2) Direct coating can be conducted on a heat source having a curved surface or an uneven surface. Thus, this technology has a wide range of applications.

(3) A productive large-area implementation can be achieved by a spin-coating method or a spraying method.

### (Structure)

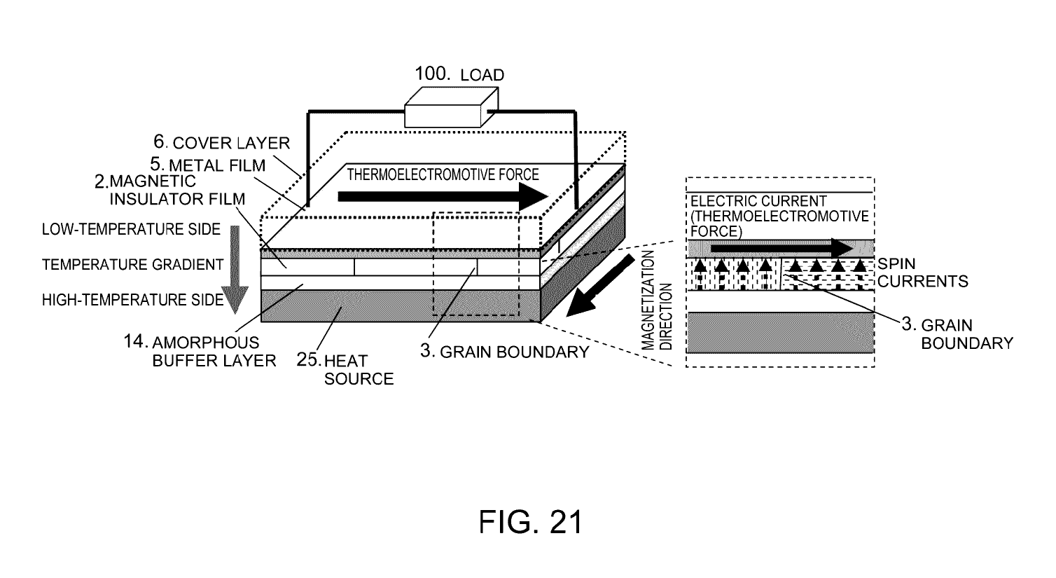

FIG. 21 shows a basic configuration of the seventh embodiment (Example 7). Unlike each of the aforementioned embodiments, which assume that a thermoelectric conversion element is produced on a substrate, a thermoelectric conversion function including a metal film 5 and a magnetic insulator film 2 is directly implemented on a heat source 25 having an amorphous buffer layer 14 formed on its surface.

The same materials as described in the third and fifth embodiments may be used for the metal film 5 and the magnetic insulator film 2.

Examples of preferable combinations of the amorphous buffer layer 14 and the heat source 25 (and supposed heat generation factors) are as follows:

A silicon oxide film layer and a silicon substrate (heat generation at an LSI or the like)

An aluminum oxide layer and an aluminum frame (heat generation at an aircraft or the like)

An iron oxide film layer and an iron frame (heat generation of an automobile body or industrial waste heat generated at a pipe or a reinforcement member)

### (Effect of Increasing an Output of Thermoelectric Conversion Due to Phonon Drag)

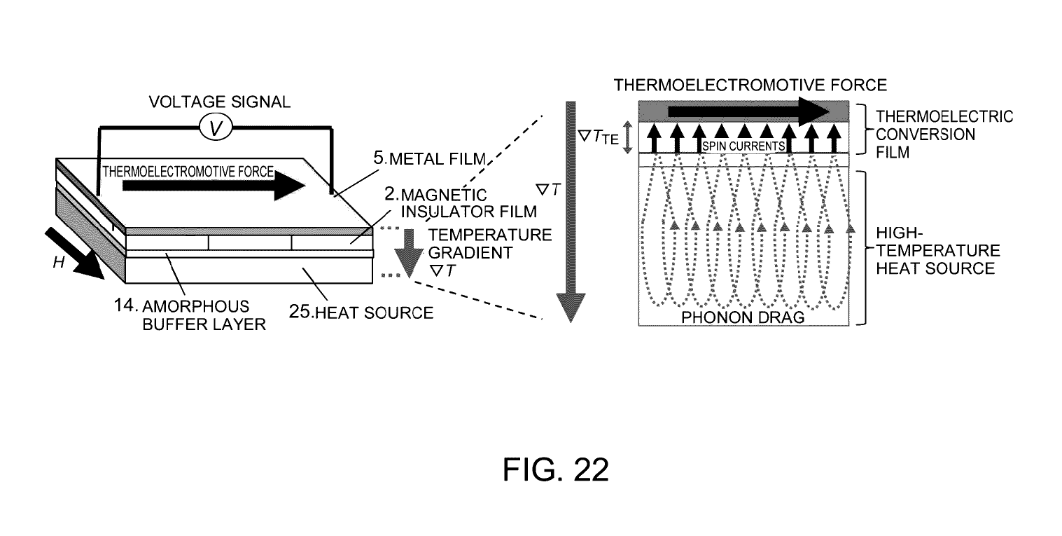

The phonon drag effect in a thermoelectric conversion function according to the seventh embodiment will be described with reference to FIG. 22.

In this seventh embodiment, the thermoelectric effect is enhanced by the “phonon drag effect” described in the fourth embodiment. When this phonon drag effect is used, spin currents in a structure of a metal film and a magnetic insulator film interact non-locally with phonons at the heat source 25 via the amorphous buffer layer 14. As a result, effective thermoelectric effect is enhanced. Specifically, not only a temperature difference ΔT_{TE} applied to the structure of the thin thermoelectric film (magnetic insulator film 2), but also a temperature distribution at the heat source 25 contributes to thermal drive of spin currents. As a result, a greater thermoelectromotive force is generated in the metal film 5.

Thus, a great thermoelectric conversion function is achieved merely by depositing a thin metal film and a magnetic insulator film that have a thickness of 1 μm or less on the heat source 25. As a result, the material cost and the implementation cost required to realize a thermoelectric conversion function can greatly be reduced by the phonon drag effect. Nevertheless, as described in the fourth embodiment, it is preferable to set the film thickness of the magnetic insulator film to be at least 50 nm in order to demonstrate high thermoelectric performance.

As described in the fourth embodiment, if the temperature of the thermoelectric film portion exceeds the Curie temperature such that the function of the magnetic material is impaired, then thermoelectric conversion becomes impossible. However, with the aforementioned phonon drag effect, thermal energy above the Curie temperature can also be recovered non-locally. Therefore, the heat source 25 may have a temperature of the Curie temperature or higher.

### Eighth Embodiment

### A Magnetic Insulator Film Structure on a Carrier Having Irregularities

In the above embodiments, a magnetic insulator film structure (magnetic insulator unified film structure) on a flat carrier and applications thereof have been described. In the following embodiments, a magnetic insulator film structure on a carrier having irregularities or some patterns and applications thereof will be described.

With the conventional structure of “a monocrystalline film and a monocrystalline substrate,” the flatness is required at the atomic level on a surface of a substrate in order to perform epitaxial growth by lattice matching between the film and the substrate. In contrast, with a structure of “a columnar crystalline film and an amorphous substrate” according to the present invention, a surface of a substrate does not necessarily need the flatness and may comprise a curved surface or a surface with irregularities or steps.

Crystal grains are likely to conflict with each other in an uneven structure due to different core growth. As a result, grain boundary surfaces perpendicular to a film are generated with a high probability. Therefore, by using this mechanism, locations at which grain boundaries are generated can be controlled when uneven patterns are formed on a substrate beforehand.

In the eighth embodiment, grain boundary surfaces are always generated substantially perpendicular to the film. Therefore, in many spin devices including a thermoelectric conversion element using a temperature gradient in a perpendicular-plane direction, performance degradation due to spin current scattering on a grain boundary surface or the like is negligibly small.

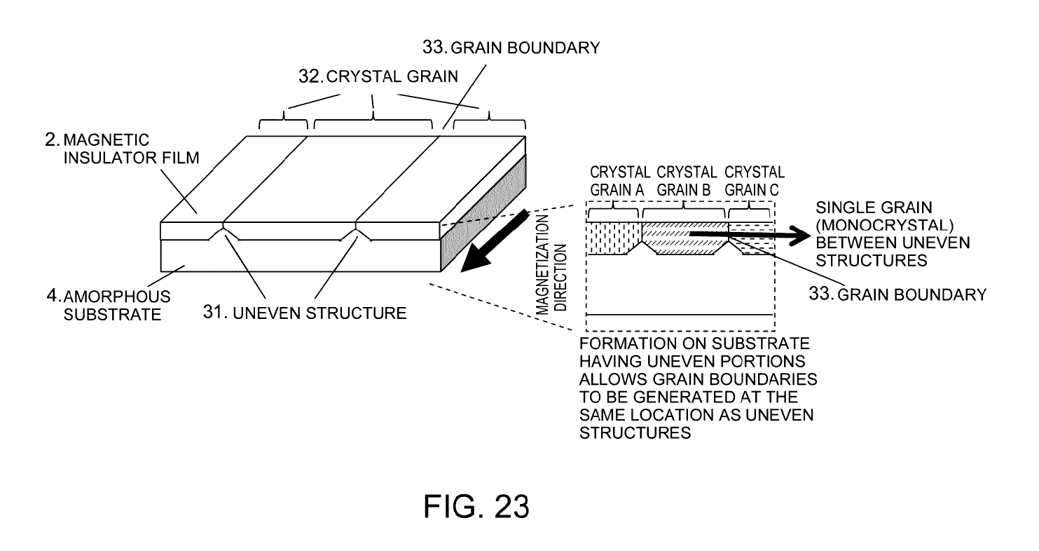

FIG. 23 shows a specific structure according to an eighth embodiment. A plurality of uneven structures 31 are formed on a surface of an amorphous substrate 4 so as to extend in parallel to each other along one direction. A magnetic insulator film 2 is deposited on the amorphous substrate 4. Crystal grains 32 growing from both sides at the time of formation of the magnetic insulator film conflict with each other right above those uneven structures 31. As a result, grain boundaries 33 are formed so as to be perpendicular to the film.

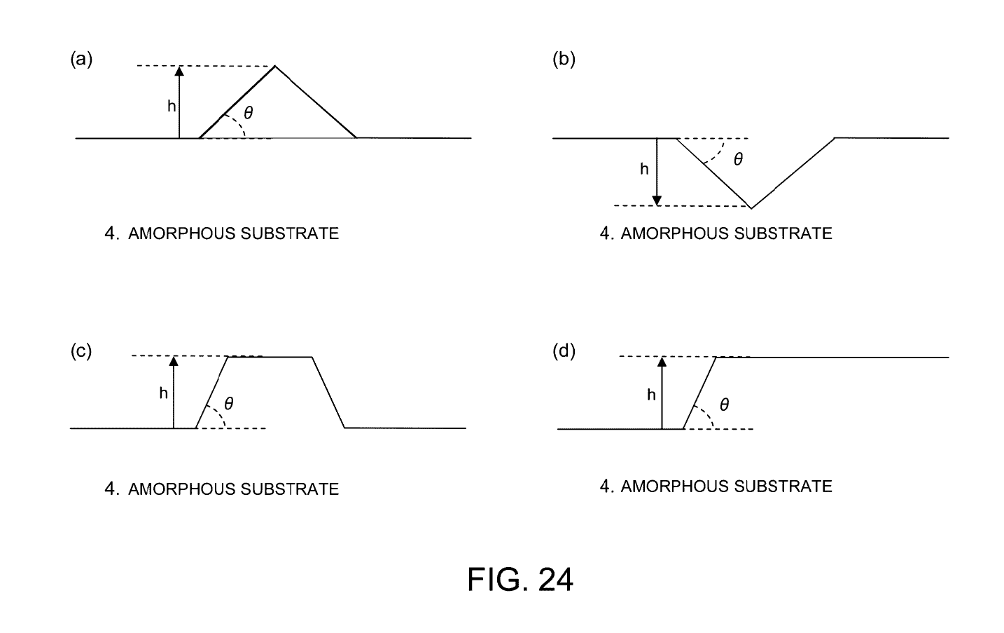

Various structures may be used for the uneven structures 31. For example, the uneven structures 31 may use a protrusion with a triangular cross-section extending along one direction as shown in the figure (a) of FIG. 24, a groove with a triangular cross-section as shown in the figure (b) of FIG. 24, a terrace with a trapezoid cross-section extending along one direction as shown in the figure (c) of FIG. 24, and a step as shown in the figure (d) of FIG. 24. When the uneven structures are intentionally generated by controlling the grain boundaries 33, it is preferable to design the size of irregularities or steps such that the height h is 3 nm or more and the step angle θ (steepness of an irregularity) is 20° or higher.

Conversely, the experiments suggest that no factors for generation of grain boundaries are found in cases of a flat substrate in which the height of the irregularities is less than 3 nm or a gentle roughness in which the step angle θ<200 even though a substrate has irregularities. In other words, a film structure that is extremely close to monocrystal is formed on such a substrate. Similarly, such a crystalline film can also be generated on a gentle curved surface.

Conventional epitaxial growth methods have been subject to two constraints: (1) A surface of a substrate to be used should have flatness at an atomic level of 1 nm or less. (2) It is preferable to design a surface of a substrate to have a crystal plane with a specific orientation.

In contrast, with a method according to the present invention, a film can be formed on various types of surfaces because crystal can grow on a rough surface or a curved surface. Therefore, greater expansion of applications is expected as compared to the conventional technology.

### Example 8

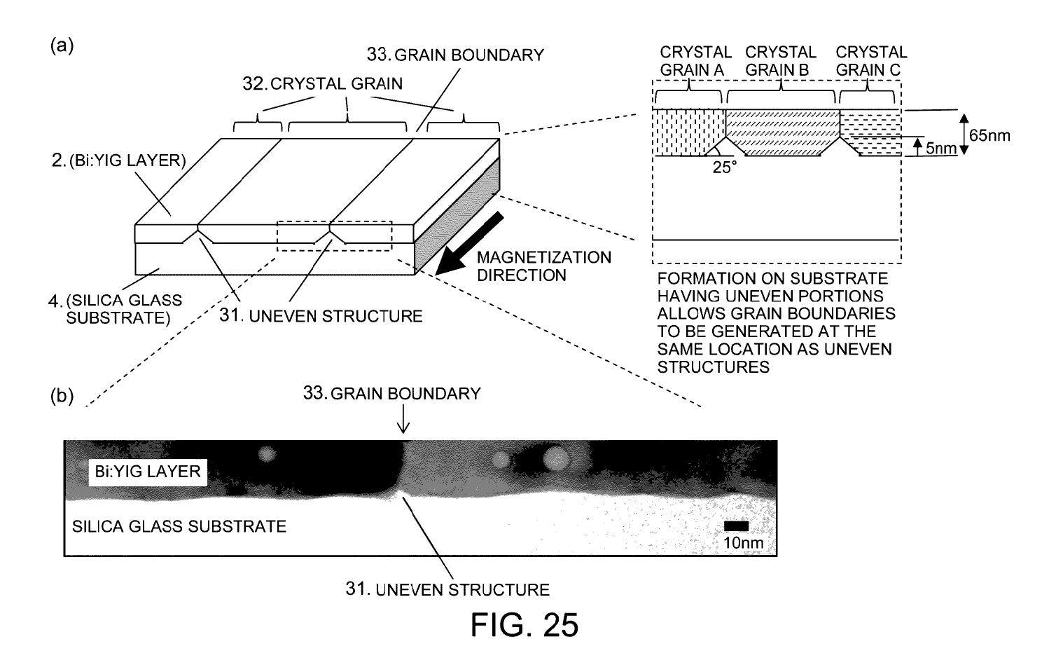

FIG. 25 shows Example 8 as a specific example of the eighth embodiment. The figure (a) of FIG. 25 illustrates an element structure. A silica glass substrate is used for an amorphous substrate 4, and a Bi:YIG film is used for a magnetic insulator film 2. A Bi:YIG film is formed in the same manner as described in Example 1.

Protrusions with a triangular cross-section extending along one direction are formed as specific uneven structures on a surface of the silica glass substrate. In Example 8, the height of the protrusions is set such that h=5 nm, and the step angle is set such that θ=25°.

The figure (b) of FIG. 25 shows a diagram modeling a cross-section TEM photograph of this magnetic film structure. As can be seen from contrast differences of the films, a grain boundary 33 is generated at the location having contrasts. Crystal grains having different crystal orientations are present on the left side and the right side of the grain boundary 33.

From the crystal structure analysis, both of those crystal grains have a garnet (11-2) surface on the interface and have a crystal orientation configuration in which the [111] direction is slightly shifted in the in-plane direction. In garnet crystal growth on a silica glass substrate, a glass surface serves as an oxygen adsorption layer. Therefore, the bottom surface of the crystalline film has a (11-2) surface with a high probability. The orientation of the in-plane direction (to which direction [111] is oriented in the plane) is not determined uniquely from the symmetry. Accordingly, it is suggested that the in-plane orientation varies depending upon domains having cores growing from different locations.

### Advantageous Effects

As described above, according to the eighth embodiment, a location at which a grain boundary surface in a perpendicular-plane direction is generated can be controlled by forming a pattern on a surface of a substrate beforehand. The density of generated grain boundaries is also controllable. If intervals between patterns are intentionally reduced, it is possible to produce a high-aspect columnar crystal structure in which the grain size d in the plane is smaller than the film thickness t (d<t). Such a pattern control of grains can be used not only for thermoelectric conversion devices in which scattering suppression of spin currents is an important factor, but also for applications of information processing devices and the like.

For example, in a magnetic recording device using a magnetic insulator, reliable reading and writing of information can be achieved by patterning a substrate such that a single grain structure is formed for each recording unit (information bit).

Furthermore, a single grain magnetic film structure may be formed into a waveguide shape by patterning a substrate. This technique can be applied to information transmission with spin currents or a logic circuit disclosed in Non-Patent Literature 3.

### Ninth Embodiment

### A Thermoelectric Conversion Element on a Substrate Having an Uneven Surface

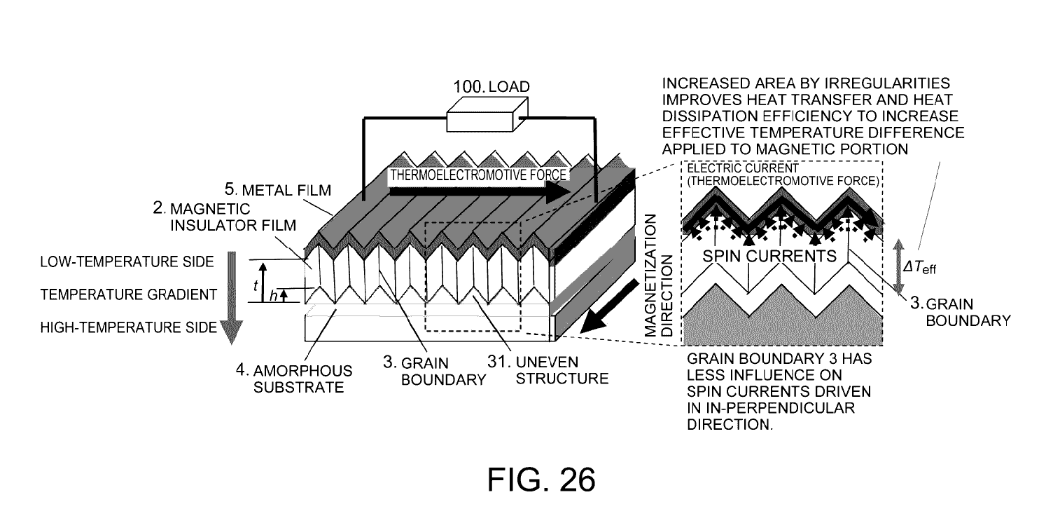

A thermoelectric conversion element according to a ninth embodiment of the present invention will be described with reference to FIG. 26. The ninth embodiment is an application of the eighth embodiment and is directed to a thermoelectric conversion element formed on a substrate having an uneven surface.

As with the eighth embodiment, uneven structures 31 having a sawtooth-like cross-section are formed on a surface of an amorphous substrate 4. A magnetic insulator film 2 is deposited on the amorphous substrate 4. The ninth embodiment differs from the previous embodiment in that a metal film 5 is formed on the magnetic insulator film 2 for deriving an electromotive force. Thus, a thermoelectromotive force generation (thermoelectric conversion) function using a temperature gradient is exhibited by the same principle as in the fourth embodiment.

In FIG. 26, the magnetic insulator film 2 and the metal film 5 are also formed into an uneven shape having a sawtooth-like cross-section in accordance with the uneven structures 31 formed on the surface of the amorphous substrate 4. FIG. 26 illustrates an example of regularly arranged uneven structures. However, the uneven structures may not necessarily be regularly arranged. Irregularities generated usually upon processing a substrate may be used as the uneven structures.

### Advantageous Effects

The conventional monocrystal deposition technology has been limited to a lattice-matched substrate that is flat at an atomic level. In contrast, a thermoelectric conversion element formed on a substrate having an uneven surface according to the ninth embodiment does not require a high level of flatness and does not need precise polishing of a substrate. Thus, the flexibility of selecting a substrate is remarkably improved.

Additionally, the following two effects are expected in view of increasing the thermoelectric conversion efficiency.

(1) The heat of a low-temperature side (or the high-temperature side) of the magnetic insulator film is dissipated (or increased) at a joint portion with the metal film. As a result, a large temperature difference can be generated at a portion of the magnetic insulator film.

(2) An electromotive force can be derived from more surfaces with an effective increase of a joint area. Therefore, an output voltage is increased.

Thus, effective thermoelectric conversion performance can further be improved as compared to a thermoelectric conversion element shown in the fourth embodiment.

It is preferable to design the height h of the irregularities to be at least 1 nm in order to demonstrate the aforementioned effects. Nevertheless, it is preferable to design the height h of the irregularities to be not more than ½ of the film thickness t in order to prevent the film quality from being degraded to a large extent.

No grain boundaries may be generated even with an uneven structure depending upon the material or production method of the magnetic insulator film. As described above, the presence of grain boundary surfaces perpendicular to the film does not exert a great influence on thermoelectric performance. Therefore, the aforementioned effects due to an uneven structure can also be obtained in such a case.

### Example 9

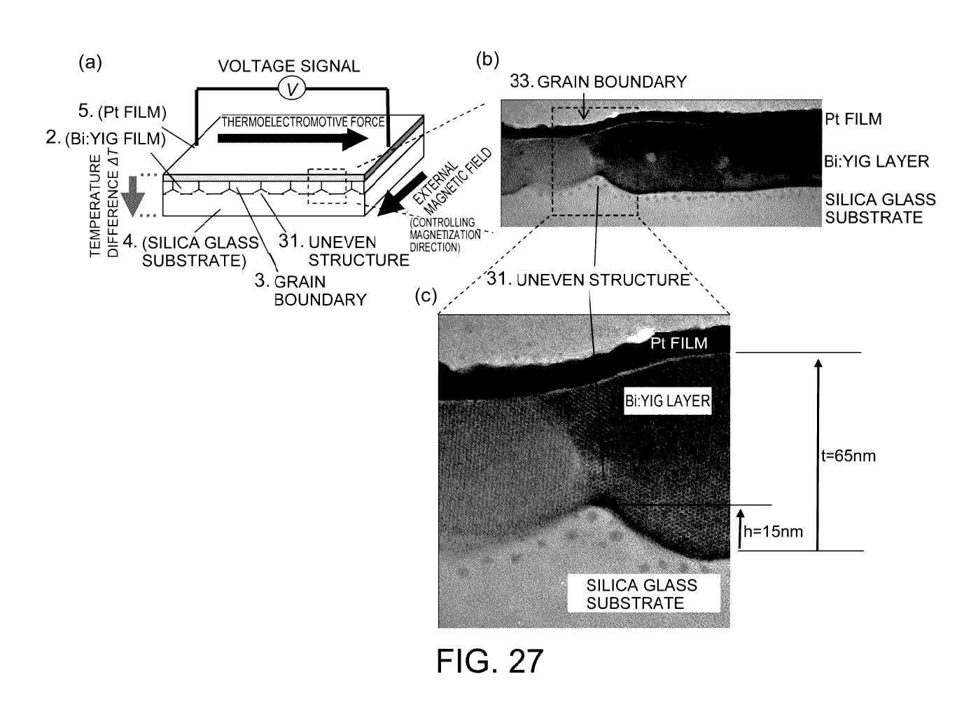

FIG. 27 shows Example 9 as a specific example of the ninth embodiment. The figure (a) of FIG. 27 illustrates an element structure. A silica glass substrate is used for an amorphous substrate 4, a Bi:YIG film is used for a magnetic insulator film 2, and a Pt film is used for a metal film 5. As shown in the figure (b) of FIG. 27, a protrusion having a triangular cross-section extending along one direction is formed as a specific uneven structure on a surface of the silica glass substrate. A grain boundary 33 is generated at the position of the protrusion. In Example 9, the height of the protrusion is set such that h=15 nm.

The Bi:YIG film and the Pt film are deposited by the same method as in Example 4. In Example 9, a Bi:YIG film is deposited by a spin-coating method using a low-viscosity material solution. Therefore, the film structure above the substrate does not greatly reflect the irregularities of the surface of the substrate. Thus, the upper portion of the Bi:YIG film and the Pt film are formed substantially in a flat state.

In this manner, grain boundaries are actually generated above the uneven structures of the amorphous substrate. However, the boundary surfaces are directed substantially perpendicular to the film. Therefore, those grain boundaries do not exert a large influence on propagation of spin currents thermally induced in the perpendicular-plane direction. In fact, the experiments found no great degradation of the thermoelectric conversion performance due to such grain boundaries.

### Tenth Embodiment

### Direct Implementation of a Thermoelectric Conversion Function on a Heat Source or a Radiator Having an Uneven Surface

In the ninth embodiment, a thermoelectric conversion element is implemented on an amorphous substrate having irregularities. In contrast, to implement a thermoelectric conversion function directly on a heat source or the like is often useful in efficiency and convenience as illustrated in the seventh embodiment. In a tenth embodiment, a thermoelectric conversion function according to the present invention is implemented directly on various kinds of heat sources having irregularities or radiators such as heat dissipation fins for dissipating heat with uneven structures.

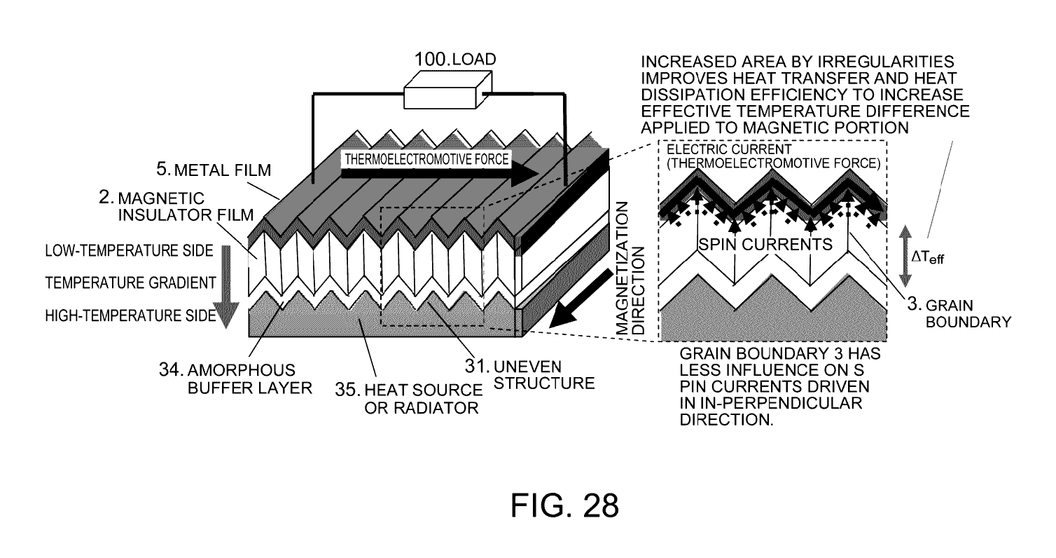

FIG. 28 illustrates a structure of the tenth embodiment. A magnetic insulator film 2 and a metal film 5 are implemented above a heat source or a radiator 35 having a plurality of uneven structures with a triangular cross-section extending along one direction on its surface while an amorphous buffer layer 34 is interposed between the magnetic insulator film 2 and the heat source or the radiator 35.

A housing of an IT device or a heat dissipation fin having irregularities or roughness is used as the heat source or the radiator 35. Furthermore, the magnetic insulator film 2 and the metal film 5 implemented above the heat source or the radiator 35 reflect the uneven structures formed on the surface of the heat source or the radiator 35 and thus have similar uneven structures.

### Advantageous Effects

In this manner, as described in the seventh embodiment, heat of a heat source can be derived and utilized for power generation more effectively by implementing a thermoelectric conversion function directly on the heat source. Particularly, if a surface of the heat source has an uneven structure as in the case of the present invention, a surface area of an interface with a thermoelectric layered product (a metal film and a magnetic insulator film) increases, so that the thermal resistance at the interface decreases. Therefore, heat can be transmitted from the heat source to the thermoelectric layered product more effectively. Thus, efficient thermal power generation can be achieved.

Furthermore, if a thermoelectric conversion function is implemented directly on a radiator having an uneven structure, heat of a surface on a low-temperature side of a thermoelectric layered product (a metal film and a magnetic insulator film) can be dissipated to the radiator more effectively. A temperature difference applied to the thermoelectric layered product effectively increases even if the same heat source is used. With this configuration, a more efficient thermal power generation can be achieved.

### (Manufacturing Method)

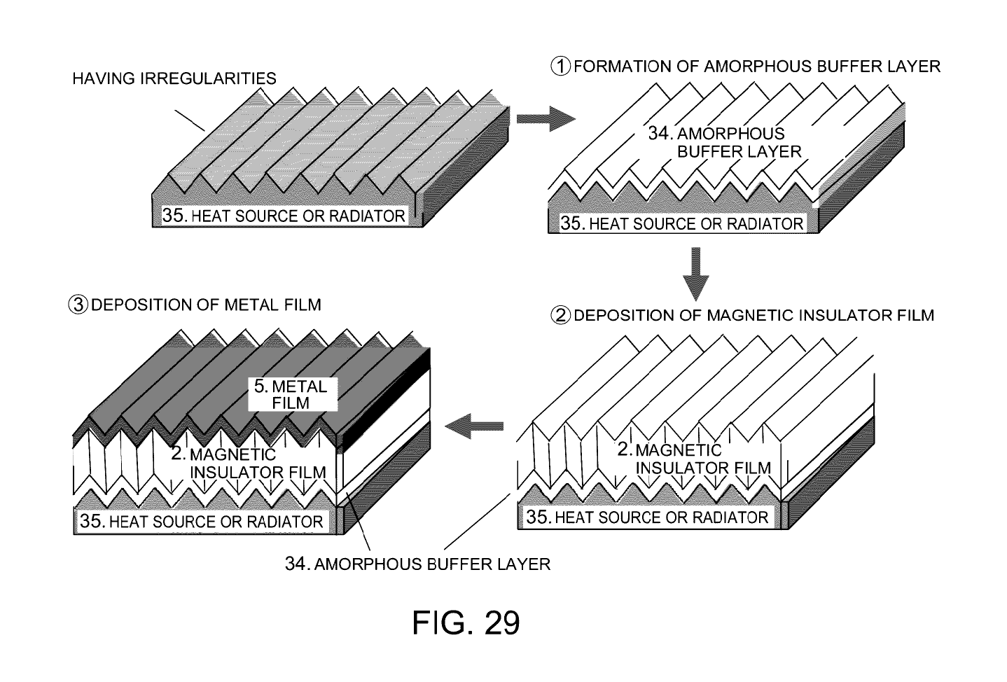

FIG. 29 illustrates a manufacturing method of this structure. First, (a) an amorphous buffer layer 34 is formed on a surface of a heat source or a radiator 35 having uneven structures in which a plurality of protrusions having a triangular cross-section are continuously formed by surface treatment such as heating (surface oxidation or the like) or chemical reaction or deposition such as coating. Then (b) a magnetic insulator film 2 having a columnar crystal structure is deposited by using a method as described in the first embodiment or the like. Subsequently, (c) a metal film 5 is deposited on the magnetic insulator film 2 by sputtering or the like. As a result, the magnetic insulator film 2 and the metal film 5 also have corrugated uneven structures in which triangular cross-sections are continuously formed.

With such an implementation method, a thermoelectric generation function integrated with a high-temperature heat source or a radiator can be implemented at various locations.

Although the present invention has been described with reference to some embodiments and specific examples thereof, it is not limited to those embodiments or examples. Those skilled in the art would make various modifications to the configuration and details of the present invention within the spirit and scope of the present invention defined in the claims.

This application claims the benefit of priority from Japanese patent application No. 2011-156618, filed Jul. 15, 2011, the disclosure of which is incorporated herein in its entirety by reference.

### DESCRIPTION OF REFERENCE NUMERALS AND SIGNS

2 magnetic insulator film
3 grain boundary
4 amorphous substrate
5 metal film
6 cover layer
14 amorphous buffer layer
25 heat source
31 uneven structure
34 amorphous buffer layer
35 heat source or radiator

1. (canceled)

2. (canceled)

3. (canceled)

4. (canceled)

5. (canceled)

6. (canceled)

7. (canceled)

8. (canceled)

9. (canceled)

10. (canceled)

11. (canceled)

12. (canceled)

13. (canceled)

14. (canceled)

15. (canceled)

16. (canceled)

17. (canceled)

18. A thermoelectric conversion element formed of a layered product for a magnetic element comprising:
a substrate comprising a material having no crystal structure on its surface;
a magnetic insulator film having a columnar crystal structure, wherein the magnetic insulator film is formed above the substrate; and
a conductive film, serving as an electrode, formed above the magnetic insulator film,
wherein the layered product is configured to generate an electromotive force in an in-plane direction of the conductive film when a temperature gradient is applied to the layered product in a direction perpendicular to a surface of the substrate.

19. The thermoelectric conversion element as recited in claim 18, wherein the conductive film comprises a material that exhibits a spin-orbit interaction.

20. The thermoelectric conversion element as recited in claim 18, wherein the magnetic insulator film has magnetization in an in-plane direction.

21. The thermoelectric conversion element as recited in claim 18, wherein the magnetic insulator film has a coercive force.

22. The thermoelectric conversion element as recited in claim 18, wherein a film thickness of the magnetic insulator film is not more than 1/10 of a film thickness of the substrate.
